(19) United States
(12) Patent Application Publication
(10) Pub. No.: US 2026/0235500 A1
(43) Pub. Date: Aug. 13, 2026

(54) SPECTROMETER EMPLOYING PUMP LIGHT SOURCE AND FLUORESCENT RADIATION

(71) Applicant: TRINAMIX GMBH, Ludwigshafen am Rhein (DE)

(72) Inventors: Szu-Yu HUANG, Ludwigshafen am Rhein (DE); Samiul ISLAM, Mannheim (DE); Henning ZIMMERMANN, Ludwigshafen am Rhein (DE); Felix SCHMIDT, Ludwigshafen am Rhein (DE); Celal Mohan OEGUEN, Ludwigshafen am Rhein (DE); Tobias BAUMGARTNER, Ludwigshafen am Rhein (DE); Till-Jonas OSTERMANN, Ludwigshafen am Rhein (DE); Bernd SCHERWATH, Ludwigshafen am Rhein (DE)

(21) Appl. No.: 19/470,945

(22) PCT Filed: Apr. 18, 2024
(86) PCT No.: PCT/EP2024/060504

§ 371 Date: Sep. 30, 2025

(30) Foreign Application Priority Data
Apr. 19, 2023 (EP) 23168744.3

(51) Int. Cl. G01N 21/31

(52) U.S. Cl. CPC G01N 21/31; G01N 2201/061; G01N 2201/062

(57) ABSTRACT

Disclosed herein are a spectrometer device and a method of obtaining spectroscopic information on at least one object. The spectrometer device includes:
i. at least one light source for generating illumination light for illuminating the object;
ii. at least one broadband detector for detecting detection light from the object in a spectral range; and
iii. at least one evaluation unit for evaluating a primary detector signal and a secondary detector signal generated by the broadband detector, for determining temperature information on the light source from one of the primary detector signal or the secondary detector signal, and for deriving the spectroscopic information on the object from the other of the primary detector signal or the secondary detector signal by taking into account the temperature information on the light source.

### TECHNICAL FIELD

The invention refers to a spectrometer device and a method of obtaining spectroscopic information on at least one object. The invention further refers to a computer program and a computer-readable storage medium for performing the method. Such devices and methods can, in general, be used for investigating or monitoring purposes, in particular, in the infrared (IR) spectral region, especially in the near-infrared (NIR) spectral region, and in the visible (VIS) spectral region, e.g. in a spectral region allowing to mimic a human's ability of color sight. However, further applications are feasible.

### BACKGROUND ART

Spectrometer devices are known to be efficient tools for obtaining information on the spectral properties of an object, when emitting, irradiating, reflecting and/or absorbing light. Spectrometer devices, thus, may assist in analyzing samples or other tasks in which information on the spectral properties of an object is of interest.

Usually, in spectrometer devices, spectral information is obtained via one or more detectors and one or more wavelength-selective optical elements, such as one or more dispersive optical elements, filters such as bandpass filters, prisms, gratings, interferometers, or the like. The detectors may comprise any type of light-sensitive element, such as one or more single or multiple pixel detectors, line detectors or array detectors having one- or two-dimensional arrays of pixels. Further, spectrometer devices may comprise one or more light sources. Thus, in spectroscopy, typically, tunable light sources, e.g. lasers, and/or broadband emitting light sources are used, such as halogen-gas filled light bulbs and/or hot filaments. However, additionally or alternatively, other light sources, such as light emitting diodes have also been proposed for the visible and the near-infrared spectral regions.

As an example, US 2010/208261 A1 describes a device for determining at least one optical property of a sample. The device comprises a tunable excitation light source for applying excitation light to the sample. The device furthermore comprises a detector for detecting detection light emerging from the sample. The excitation light source comprises a light-emitting diode array, which is configured at least partly as a monolithic light-emitting diode array. The monolithic light-emitting diode array comprises at least three light-emitting diodes each having a different emission spectrum.

U.S. Pat. No. 8,164,050 B2 describes a multi-channel source assembly for downhole spectroscopy that has individual sources that generate optical signals across a spectral range of wavelengths. A combining assembly optically combines the generated signals into a combined signal and a routing assembly that splits the combined signal into a reference channel and a measurement channel. Control circuitry electrically coupled to the sources modulates each of the sources at unique or independent frequencies during operation.

Further, U.S. Pat. No. 7,061,618 B2 describes integrated spectroscopy systems, wherein in some examples, integrated tunable detectors, using one or multiple Fabry-Pérot tunable filters, are provided. Other examples use integrated tunable sources combining one or multiple diodes, such as superluminescent light emitting diodes (SLED), and a Fabry-Pérot tunable filter or etalon.

Further, U.S. Pat. No. 5,475,221 A describes an optical device which uses an array of light emitting diodes, controlled by multiplexing schemes, to replace conventional broad band light sources in devices such as spectrometers.

Further, US 2021/293620 A1 discloses a spectrometer comprising: an illumination device for illuminating a spectrometric measurement region; a detection unit for detecting electromagnetic radiation coming from the spectrometric measurement region; and a spectral element, which is arranged in the beam path between the illumination device and the detection unit. The illumination device comprises: a light emitting diode having a first central wavelength, which is designed to emit first electromagnetic radiation having a first spectrum; and a luminescent element for converting a first component of the first electromagnetic radiation having the first spectrum into second electromagnetic radiation having a second spectrum. The first central wavelength is 550 nm or 3000 nm or has a value between 550 nm and 3000 nm. The first spectrum and the second spectrum have an overlap.

Further, US 2013/093936 A1 discloses an energy dispersion device, a spectrograph and a method that can be used to evaluate the composition of matter on site without the need for specialized training or expensive equipment. The energy dispersion device or spectrograph can be used with a digital camera or cell phone. A device of the invention includes a stack of single- or double-dispersion diffraction gratings that are rotated about their normal giving rise to a multiplicity of diffraction orders from which meaningful measurements and determinations can be made with respect to the qualitative or quantitative characteristics of matter.

Further, WO 2021/058260 A1 discloses a spectrometer device and a calibration method for a spectrometer device. A calibrating element having one or more known extinction curves is disposed in the beam path between light emitter and photodetector of the spectrometer device. A precise correlation between control of the spectral element and corresponding wavelength can be generated by determining the setting of a spectral element that corresponds to an extinction curve of the calibrating element.

Furthermore, EP 3 961 826 A1 discloses a light emitting device including a light source configured to emit a primary light, a first phosphor that absorbs the primary light and converts the primary light into a first wavelength-converted light having a wavelength longer than that of the primary light, and a second phosphor that absorbs the primary light and converts the primary light into a second wavelength-converted light having a wavelength longer than that of the primary light. The first wavelength-converted light is a fluorescence having a light component over an entire wavelength range of 700 nm or more to 800 nm or less. The second wavelength-converted light is a fluorescence having a peak where a fluorescence intensity shows a maximum value in a wavelength range of 380 nm or more to less than 700 nm. The first wavelength-converted light has a 1/10 afterglow time longer than that of the second wavelength-converted light.

Despite the advantages achieved by known methods and devices, several technical challenges remain in the field of spectroscopy and spectroscopic devices, specifically for spectroscopy in the near-infrared range. Spectrometer systems having a combination of LED and phosphor luminescence coatings as light sources may suffer from conversion inefficiency in certain wavelength ranges, such as the infrared wavelength range, and, thus, may have significant amount of illumination outside of the intended target wavelength range. Thus, optical power in this wavelength range is generally wasted since no spectroscopic information can be gained from these wavelengths. Further, in contrast to industry applications, where specialized hardware can be employed for specific measurement setups, consumer spectroscopy is desired to cover a large number of applications, specifically in order to find mass-market appeal. Many of these applications may require investigation of spatially heterogeneous materials, which generally have different optical properties, such as differing penetration depth for different wavelength ranges. It is often required to obtain spectroscopic information in depth of these samples, also referred to as spatial distribution.

However, technical challenges may arise from the fact that, in the field of consumer spectroscopy, compact and integrated spectrometer devices, for example spectrometer devices integrated in wearables or the like, can only be provided with limited resources, for example a single emitter and detector type, in order to cover the desired application ranges. Solutions are known which use an emission spectrum defined for a single specific application, for example using a single chip white LED which specifically may comprise a complementary color mixture of blue pump light and yellow fluorescence spectrum from a phosphor to generate white light. These systems may not be able to address multiple spectroscopic applications.

### Problem to be Solved

It is therefore desirable to provide methods and devices, which at least partially address the above-mentioned technical challenges and at least substantially avoid the disadvantages of known methods and devices. In particular, it is an object of the present invention to provide a spectrometer device and a method of obtaining spectroscopic information on at least one object which are capable of addressing spectroscopic applications in the field of consumer spectroscopy.

### SUMMARY

This problem is addressed by a spectrometer device for obtaining spectroscopic information on at least one object, by a method of obtaining spectroscopic information on at least one object, and by a computer program and a computer-readable storage medium for performing the method with the features of the independent claims. Advantageous embodiments which might be realized in an isolated fashion or in any arbitrary combinations are listed in the dependent claims as well as throughout the specification.

In a first aspect of the present invention, a spectrometer device for obtaining spectroscopic information on at least one object is disclosed.

The term “spectrometer device” as used herein is a broad term and is to be given its ordinary and customary meaning to a person of ordinary skill in the art and is not to be limited to a special or customized meaning. The term specifically may refer, without limitation, to an optical device configured for acquiring at least one item of spectral information on at least one object. Specifically, the at least one item of spectral information may refer to at least one optical property or optically measurable property which is determined as a function of a wavelength, for one or more different wavelengths. More specifically, the optical property or optically measurable property, as well as the at least one item of spectral information, may relate to at least one property characterizing at least one of a transmission, an absorption, a reflection and an emission of the at least one object, either by itself or after illumination with external light. The at least one optical property may be determined for one or more wavelengths. The spectrometer device specifically may form an apparatus which is capable of recording a signal intensity with respect to the corresponding wavelength of a spectrum or a partition thereof, such as a wavelength interval, wherein the signal intensity may, specifically, be provided as an electrical signal which may be used for further evaluation.

The spectrometer device, as an example, may be or may comprise a device which allows for a measurement of at least one spectrum, e.g. for the measurement of a spectral flux, specifically as a function of a wavelength or detection wavelength. The spectrum may be acquired, as an example, in absolute units or in relative units, e.g. in relation to at least one reference measurement. Thus, as an example, the acquisition of the at least one spectrum specifically may be performed either for a measurement of the spectral flux (unit W/nm) or for a measurement of a spectrum relative to at least one reference material (unit 1), which may describe the property of a material, e.g., reflectance over wavelength. Additionally or alternatively, the reference measurement may be based on a reference light source, an optical reference path, a calculated reference signal, e.g. a calculated reference signal from literature, and/or on a reference device.

Specifically, the at least one spectrometer device may be a diffusive reflective spectrometer device configured for acquiring spectral information from the light which is diffusively reflected by the at least one object, e.g. the at least one sample. Additionally or alternatively, the at least one spectrometer device may be or may comprise an absorption- and/or transmission-spectrometer. In particular, measuring a spectrum with the spectrometer device may comprise measuring absorption in a transmission configuration. Specifically, the spectrometer device may be configured for measuring absorption in a transmission configuration. As outlined above, however, other types of spectrometer devices are also feasible.

The at least one spectrometer device, specifically and as will be outlined in further detail below, may comprise at least one light source which, as an example, may be at least one of a tunable light source, a light source having at least one fixed emission wavelength and a broadband light source. The spectrometer device, as will be outlined in further detail below, further comprises at least one detector device configured for detecting light, such as light which is at least one of transmitted, reflected or emitted from the at least one object. The spectrometer device further may comprise, as will be outlined in further detail below, at least one wavelength-selective element, such as at least one of a grating, a prism, or a filter, e.g. a length variable filter having varying transmission properties over its lateral extension. The wavelength-selective element may be used for separating incident light into a spectrum of constituent wavelength signals whose respective intensities are determined by employing a detector such as a detector having a detector array as described below in more detail.

The spectrometer device, specifically, may be a portable spectrometer device. The term “portable” as used herein is a broad term and is to be given its ordinary and customary meaning to a person of ordinary skill in the art and is not to be limited to a special or customized meaning. The term specifically may refer, without limitation, to the property of at least one object of being moved by human force, such as by a single user. Specifically, the object characterized by the term “portable” may have a weight not exceeding 10 kg, specifically not exceeding 5 kg, more specifically not exceeding 1 kg, or even not exceeding 500 g. Additionally or alternatively, the dimensions of the object characterized by the term “portable” may be such that the object extends by no more than 0.3 m into any dimension, specifically by no more than 0.2 m into any dimension. The object, specifically, may have a volume of no more than 0.03 m³, specifically of no more than 0.01 m³, more specifically no more than 0.001 m³ or even no more than 500 mm³. In particular, as an example, the portable spectrometer device may have dimensions of e.g. 10 mm by 10 mm by 5 mm. Specifically, the portable spectrometer device may be part of a mobile device or may be attachable to a mobile device, such as a notebook computer, a tablet, a cell phone, such as a smart phone, a smartwatch and/or a wearable computer, also referred to as “wearable”, e.g. a body borne computer such as a wrist band or a watch. In particular, the a weight of the spectrometer device, specifically the portable spectrometer device, may be in the range from 1 g to 100 g, more specifically in the range from 1 g to 10 g.

The term “spectroscopic information”, also referred to as “spectral information” or as “an item of spectral information”, as used herein is a broad term and is to be given its ordinary and customary meaning to a person of ordinary skill in the art and is not to be limited to a special or customized meaning. The term specifically may refer, without limitation, to a particular item of information, e.g. on at least one object and/or radiation emitted by at least one object, characterizing at least one optical property of the object, more specifically at least one item of information characterizing, e.g. qualifying and/or quantifying, at least one of a transmission, an absorption, a reflection and an emission of the at least one object. As an example, the at least one item of spectral information may comprise at least one intensity information, e.g. information on an intensity of light being at least one of transmitted, absorbed, reflected or emitted by the object, e.g. as a function of a wavelength or wavelength sub-range over one or more wavelengths, e.g. over a range of wavelengths. Specifically, the intensity information may correspond to or be derived from the signal intensity, specifically the electrical signal, recorded by the spectrometer device with respect to a wavelength or a range of wavelengths of the spectrum.

The spectrometer device specifically may be configured for acquiring at least one spectrum or at least a part of a spectrum of detection light propagating from the object to the spectrometer. The spectrum may describe the radiometric unit of spectral flux, e.g. given in units of watt per nanometer (W/nm), or other units, e.g. as a function of the wavelength of the detection light. Thus, the spectrum may describe the optical power of light, e.g. in the NIR spectral range, in a specific wavelength band. The spectrum may contain one or more optical variables as a function of the wavelength, e.g. the power spectral density, electric signals derived by optical measurements and the like. The spectrum may indicate, as an example, the power spectral density and/or the spectral flux of the object, e.g. of a sample, e.g. relative to a reference sample, such as a transmittance and/or a reflectance of the object, specifically of the sample.

The spectrum, as an example, may comprise at least one measurable optical variable or property of the detection light and/or of the object, specifically as a function of the illumination light and/or the detection light. As an example, the at least one measurable optical variable or property may comprise at least one at least one radiometric quantity, such as at least one of a spectral density, a power spectral density, a spectral flux, a radiant flux, a radiant intensity, a spectral radiant intensity, an irradiance, a spectral irradiance. Specifically, as an example, the spectrometer device, specifically the detector, may measure the irradiance in Watt per square meter (W/m²), more specifically the spectral irradiance in Watt per square meter per nanometer (W/m²/nm). Based on the measured quantity the spectral flux in Watt per nanometer (W/nm) and/or the radiant flux in Watt (W) may be determined, e.g. calculated, by taking into account an area of the detector.

The term “object” as used herein is a broad term and is to be given its ordinary and customary meaning to a person of ordinary skill in the art and is not to be limited to a special or customized meaning. The term specifically may refer, without limitation, to an arbitrary body, chosen from a living object and a non-living object. Thus, as an example, the at least one object may comprise one or more articles and/or one or more parts of an article, wherein the at least one article or the at least one part thereof may comprise at least one component which may provide a spectrum suitable for investigations. Additionally or alternatively, the object may be or may comprise one or more living beings and/or one or more parts thereof, such as one or more body parts of a human being, e.g. a user, and/or an animal. The object specifically may comprise at least one sample which may fully or partially be analyzed by spectroscopic methods. As an example, the object may be or may comprise at least one of: human or animal skin; edibles, such as fruits; plastics and textile.

The spectrometer device comprises:
i. at least one light source for generating illumination light for illuminating the object, the light source comprising at least one light-emitting diode and at least one luminescent material for light-conversion of primary light generated by the light-emitting diode into secondary light, wherein the illumination light at least partially comprises the primary light and the secondary light;
ii. at least one broadband detector for detecting detection light from the object in a spectral range at least partially comprising the spectral ranges of the primary light and the secondary light, wherein the broadband detector is configured for generating at least one primary detector signal upon detecting the detection light in the spectral range of the primary light, wherein the broadband detector is further configured for generating at least one secondary detector signal upon detecting the detection light in the spectral range of the secondary light; and
iii. at least one evaluation unit for evaluating the primary detector signal and the secondary detector signal generated by the broadband detector, for determining temperature information on the light source from one of the primary detector signal or the secondary detector signal, and for deriving the spectroscopic information on the object from the other of the primary detector signal or the secondary detector signal by taking into account the temperature information on the light source.

The term “light” as used herein is a broad term and is to be given its ordinary and customary meaning to a person of ordinary skill in the art and is not to be limited to a special or customized meaning. The term specifically may refer, without limitation, to electromagnetic radiation in one or more of the infrared, the visible and the ultraviolet spectral range. Herein, the term “ultraviolet spectral range”, generally, refers to electromagnetic radiation having a wavelength of 1 nm to 380 nm, preferably of 100 nm to 380 nm. Further, in partial accordance with standard ISO-21348 in a valid version at the date of this document, the term “visible spectral range”, generally, refers to a spectral range of 380 nm to 760 nm. The term “infrared spectral range” (IR) generally refers to electromagnetic radiation of 760 nm to 1000 μm, wherein the range of 760 nm to 1.5 μm is usually denominated as “near-infrared spectral range” (NIR) while the range from 1.5 μ to 15 μm is denoted as “mid infrared spectral range” (MidIR) and the range from 15 μm to 1000 μm as “far-infrared spectral range” (FIR). Preferably, light used for the typical purposes of the present invention is light in the infrared (IR) spectral range, more preferred, in the near-infrared (NIR) and/or the mid infrared spectral range (MidIR), especially the light having a wavelength of 1 μm to 5 μm, preferably of 1 μm to 3 μm. This is due to the fact that many material properties or properties on the chemical constitution of many objects may be derived from the near-infrared spectral range. It shall be noted, however, that spectroscopy in other spectral ranges is also feasible and within the scope of the present invention.

The term “light source” as used herein is a broad term and is to be given its ordinary and customary meaning to a person of ordinary skill in the art and is not to be limited to a special or customized meaning. The term specifically may refer, without limitation, to an arbitrary device configured for generating or providing light in the sense of the above-mentioned definition. The light source specifically may be or may comprise at least one electrical light source, such as an electrically driven light source. The light source may be part of the spectrometer device in a housing of the spectrometer device. Alternatively or additionally, the at least one light source can also be arranged outside a housing, for example as a separate light source. The light source can be arranged separately from the object and illuminate the object from a distance.

In spectroscopy, various sources and paths of light are to be distinguished. In the context of the present invention, a nomenclature is used which, firstly, denotes light propagating from the light source to the object as “illuminating light” or “illumination light”. Secondly, light propagating from the object to the detector is denoted as “detection light”. The detection light may comprise at least one of illumination light reflected by the object, illumination light scattered by the object, illumination light transmitted by the object, luminescence light generated by the object, e.g. phosphorescence or fluorescence light generated by the object after optical, electrical or acoustic excitation of the object by the illumination light or the like. Thus, the detection light may directly or indirectly be generated through the illumination of the object by the illumination light.

The term “illuminate”, as used herein, is a broad term and is to be given its ordinary and customary meaning to a person of ordinary skill in the art and is not to be limited to a special or customized meaning. The term specifically may refer, without limitation, to the process of exposing at least one element to light.

Further, as will be outlined in detail below, within the light source itself, a distinction may be made between various light sources, such as primary light sources and secondary light sources. Thus, as will be outlined in further detail below, “primary light”, also referred to as “pump light”, may be generated by a primary light source such as at least one light-emitting diode and may subsequently be transformed into “secondary light”, such as by using light conversion, e.g. through the luminescent material, such through one or more phosphor materials. The illumination light, as outlined above, at least partially comprises the primary light and the secondary light. Specifically, the illumination light may comprise those parts of the primary light generated by the light-emitting diode which are not converted into the secondary light by the luminescent material, e.g. due to conversion inefficiency of the luminescent material, and the secondary light.

As outlined above, the light source comprises at least one light-emitting diode and at least one luminescent material for light-conversion of primary light generated by the light-emitting diode into secondary light.

The term “light-emitting diode” or briefly “LED”, as used herein, is a broad term and is to be given its ordinary and customary meaning to a person of ordinary skill in the art and is not to be limited to a special or customized meaning. The term specifically may refer, without limitation, to an optoelectronic semiconductor device capable of emitting light when an electrical current flows through the device. The optoelectronic semiconductor device may be configured for generating the light due to various physical processes, including one or more of spontaneous emission, induced emission, decay of metastable excited states and the like. Thus, as an example, the light-emitting diode, may comprise one or more of: a light-emitting diode based on spontaneous emission of light, in particular an organic light emitting diode, a light-emitting diode based on superluminescence (sLED), or a laser diode (LD). In the following, without narrowing the possible embodiments of the light-emitting diode to any of the before-mentioned physical principles or setups, the abbreviation “LED” will be used for any type of light-emitting diode. Specifically, the LED may comprise at least two layers of semiconductor material, wherein light may be generated at at least one interface between the at least two layers of semiconductor material, specifically due to a recombination of positive and negative electrical charges, e.g. due to electron-hole recombination. The at least two layers of semiconductor material may have differing electrical properties, such as at least one of the layers being an n-doped semiconductor material and at least one of the layers being a p-doped semiconductor material. Thus, as an example, the LED may comprise at least one pn-junction and/or at least one pin-set up. It shall be noted, however, that other device structures are feasible, too. The at least one semiconductor material may specifically be or may comprise at least one inorganic semiconducting material. It shall be noted, however, that organic semiconducting materials may be used additionally or alternatively.

Generally, the LED may convert electrical current into light, specifically into the primary light, more specifically into blue primary light, as will be outlined in further detail below. The LED, thus, specifically may be a blue LED. The LED may be configured for generating the primary light, also referred to as the “pump light”. Thus, the LED may also be referred to as the “pump LED”. The LED specifically may comprise at least one LED chip and/or at least one LED die. Thus, the semiconductor element of the LED may comprise an LED bare chip.

Various types of LEDs suitable for generating the primary light are known to the skilled person and may also be applied in the present invention. Specifically, p-n-diodes may be used. As an example, one or more LEDs selected from the group of an LED on the basis of indium gallium nitride (InGaN), an LED on the basis of GaN, an LED on the basis of InGaN/GaN alloys or combinations thereof and/or other LEDs may be used. Additionally or alternatively, quantum well LEDs may also be used, such as one or more quantum well LEDs on the basis of InGaN. Additionally or alternatively, superluminescence LEDs (sLED) and/or quantum cascade lasers may be used.

The term “luminescence” as used herein is a broad term and is to be given its ordinary and customary meaning to a person of ordinary skill in the art and is not to be limited to a special or customized meaning. The term specifically may refer, without limitation, to the process of spontaneous emission of light by a substance not resulting from heat. Specifically, luminescence may refer to a cold-body radiation. More specifically, the luminescence may be initiated or excited by irradiation of light, in which case the luminescence is also referred to as “photoluminescence”. The property of a material being capable of performing luminescence, in the context of the present invention, is referred to by the adjective “luminescent”. The at least one luminescent material specifically may be a photoluminescent material, i.e. a material which is capable of emitting light after absorption of photons or excitation light. Specifically, the luminescent material may have a positive Stokes shift, which generally may refer to the fact that the secondary light is red-shifted with respect to the primary light.

The at least one luminescent material, thus, may form at least one converter, also referred to as a light converter, transforming primary light into secondary light having different spectral properties as compared to the primary light. Specifically, a spectral width of the secondary light may be larger than a spectral width of the primary light, and/or a center of emission of the secondary light may be shifted, specifically red-shifted, compared to the primary light. Specifically, the at least one luminescent material may have an absorption in the ultraviolet and/or blue spectral range and an emission in the near-infrared and/or infrared spectral range. Thus, generally, the luminescent material or converter may form at least one component of the LED, specifically of the phosphor LED, converting primary light or pump light, specifically in the blue spectral range, into light having a longer wavelength, e.g. in the near-infrared or infrared spectral range.

Various types of conversion and/or luminescence are known and may be used in the context of the present invention. Thus, specifically, the conversion can occur via a dipole-allowed transition in the luminescent material, also referred to as fluorescence, and/or via a dipole-forbidden, thus long-lived, transition in the luminescent material, often also referred to as phosphorescence.

The luminescent material, specifically, may, thus, form at least one converter or light converter. The luminescent material may form at least one of a converter platelet, a luminescent and specifically a fluorescent coating on the LED and phosphor coating on the LED. The luminescent material may, as an example, comprise one or more of the following materials: Cerium-doped YAG (YAG:Ce3+, or Y3Al5O12:Ce3+); rare-earth-doped Sialons; copper- and aluminum-doped zinc sulfide (ZnS:Cu,Al).

The light source may comprise a phosphor light-emitting diode. Specifically, the LED and the luminescent material, together, may form a so-called “phosphor LED”. Consequently, the term “phosphor light-emitting diode” or briefly “phosphor LED”, as used herein, is a broad term and is to be given its ordinary and customary meaning to a person of ordinary skill in the art and is not to be limited to a special or customized meaning. The term specifically may refer, without limitation, to a combination of at least one light-emitting diode configured for generating primary light or pump light, and at least one luminescent material, also referred to as a “phosphor”, configured for light-conversion of the primary light generated by the light-emitting diode. The phosphor LED may form a packaged LED light source, including the LED die, e.g. a blue LED emitting blue pump light, as well as the phosphor, which, as an example, fully or partially coats the LED, which is, as an example, configured for converting the primary light or blue light into light having differing spectral properties, specifically into near-infrared light. Generally, the phosphor LED may be packaged in one housing or may be unpackaged. Thus, the LED and the at least one luminescent material for light-conversion of the primary light generated by the light-emitting diode may specifically be housed in a common housing. Alternatively, however, the LED may also be an unhoused or bare LED which may fully or partially be covered with the luminescent material, such as by disposing one or more layers of the luminescent material on the LED die. The phosphor LED, generally, may form an emitter or light source by itself.

In the light source, specifically the phosphor LED, the at least one luminescent material specifically may be located with respect to the light-emitting diode such that a heat transfer from the light-emitting diode to the luminescent material is possible. More specifically, the luminescent material may be located such that a heat transfer by one or both of thermal radiation and heat conduction is possible, more preferably by heat conduction. Thus, as an example, the luminescent material may be in thermal contact and/or in physical contact with the light-emitting diode. As an example, the luminescent material may form one or more coatings or layers in contact with or in close proximity to the light-emitting diode, such as with one or more of the semiconductor materials of the light-emitting diode. Thereby, generally, the luminescent material and the light-emitting diode may be thermally coupled. The terms “thermal coupling” or briefly “thermally coupled”, as used herein, are broad terms and are to be given their ordinary and customary meaning to a person of ordinary skill in the art and are not to be limited to a special or customized meaning. The terms specifically may refer, without limitation, to a temperature difference of 0.1 K to 5 K, in particular of 0.1 K to 1 K, specifically of 0.1 K to 0.5 K, which exists between the light-emitting diode and the luminescent material during operation of the light source. In other words: At a given power spectral density of the primary light and the secondary light, a single temperature can be assigned to both the light-emitting diode and the luminescent material, i.e. the light source. As an advantage of the thermal coupling, the spectrum of the light-emitting diode and the spectrum of the luminescent material exhibit an individual, but characteristic temperature dependence. As a further advantage that is disclosed below in more detail, one of the spectra or a portion thereof can be used for determining the single temperature assigned to the light source, whereinafter the single temperature of the light source as determined in this fashion can be used for deriving the spectroscopic information on the object from the other spectrum, whereby the temperature information about the light source is taken into account.

The at least one luminescent material specifically may form at least one layer. Generally, various alternatives of positioning the luminescent material with respect to the light-emitting diode are feasible, alone or in combination. Firstly, the luminescent material, e.g., at least one layer of the luminescent material, such as the phosphor, may be positioned directly on the light-emitting diode, which is also referred to as a “direct attach”, e.g. with no material in between the LED and the luminescent material or with one or more transparent materials in between, such as with one or more transparent materials, specifically transparent for the primary light, in between the LED and the luminescent material. Thus, as an example, a coating of the luminescent material may be placed directly or indirectly on the LED. Additionally or alternatively, the luminescent material, as an example, may form at least one converter body, such as at least one converter disk, which may be placed on top of the LED, e.g. by adhesive attachment of the converter body to the LED. Additionally or alternatively, the luminescent material may also be placed in a remote fashion, such that the primary light from the LED has to pass an intermediate optical path before reaching the luminescent material. This placement may also be referred to as a “remote placement” or as a “remote phosphor”. Again, as an example, the luminescent material in the remote placement may form a solid body or converter body, such as a disk or converter disk. Further, in case of the remote placement, the luminescent material may also be a coating. In particular, an object which is transmitting light, e.g. a thin glass substrate, module window, comprising and/or being made of glass or plastics, may be coated with the phosphor. Alternatively, a reflective surface may be coated with the phosphor. This could be a flat or rough mirror, which may comprise and/or be made of a high-reflective index material substrate, e.g. silicon, or a gold, silver, aluminum or chromium coated flat or rough surface, e.g. glass, or a plastic. In the intermediate optical path, one or more optical elements may be placed, such as one or more of a lens, a prism, a grating, a mirror, an aperture or a combination thereof. Thus, specifically, an optical system having imaging properties may be placed in between the LED and the luminescent material, in the intermediate optical path. Thereby, as an example, the primary light may be focused, or bundled onto the converter body.

The primary light may be at least partially located in a spectral range of 380 nm to 1000 nm, specifically in a spectral range of 420 nm to 940 nm, more specifically in a spectral range of 420 nm to 830 nm, more specifically in a spectral range of 440 nm to 830 nm. For example, the primary light may be located in a spectral range between a first wavelength and a second wavelength, wherein the first wavelength is selected from 380 nm, 420 nm and 440 nm, wherein the second wavelength is selected from 1000 nm, 940 nm, 830 nm, 460 nm and 455 nm. For example, the LED may comprise a blue LED having a primary emission range at least partially located in the spectral range of 420 nm to 460 nm, specifically in a spectral range of 440 nm to 455 nm, more specifically at 440 nm.

The primary light generated by the light-emitting diode which may not be converted into the secondary light by the luminescent material is at least partially located in a spectral range of 420 nm to 940 nm, more specifically in a spectral range of 420 nm to 830 nm, more specifically in a spectral range of 440 nm to 830 nm. By way of example, the primary light may be located in a spectral range between a first wavelength and a second wavelength, wherein the first wavelength may be selected from 380 nm, 420 nm and 440 nm, and wherein the second wavelength may be selected from 1000 nm, 940 nm, 830 nm, 460 nm and 455 nm.

The secondary light may be at least partially located in a spectral range of 1 μm to 5 μm, specifically in a spectral range of 1.5 μm to 3 μm, more specifically in a spectral range of 1.5 μm to 2.5 μm. For example, the secondary light may be located in a spectral range between a first wavelength and a second wavelength, wherein the first wavelength comprises at least one of 1 μm or 1.5 μm, wherein the second wavelength is selected from 5 μm, 3 μm and 1.5 μm.

As outlined above, the spectrometer device comprises at least one broadband detector for detecting detection light from the object in a spectral range at least partially comprising the spectral ranges of the primary light and the secondary light. The verb “to detect” as used herein is a broad term and is to be given its ordinary and customary meaning to a person of ordinary skill in the art and is not to be limited to a special or customized meaning. The term specifically may refer, without limitation, to the process of at least one of determining, measuring and monitoring at least one parameter, qualitatively and/or quantitatively, such as at least one of a physical parameter, a chemical parameter and a biological parameter. Specifically, the physical parameter may be or may comprise an electrical parameter. Consequently, the term “detector” as used herein is a broad term and is to be given its ordinary and customary meaning to a person of ordinary skill in the art and is not to be limited to a special or customized meaning. The term specifically may refer, without limitation, to an arbitrary device configured for detecting, i.e. for at least one of determining, measuring and monitoring, at least one parameter, qualitatively and/or quantitatively, such as at least one of a physical parameter, a chemical parameter and a biological parameter. The detector may be configured for generating at least one detector signal, more specifically at least one electrical detector signal, such as an analogue and/or a digital detector signal, the detector signal providing information on the at least one parameter measured by the detector. The detector signal may directly or indirectly be provided by the detector to the evaluation unit, such that the detector and the evaluation unit may be directly or indirectly connected. The detector signal may be used as a “raw” detector signal and/or may be processed or preprocessed before further used, e.g. by filtering and the like. Thus, the detector may comprise at least one processing device and/or at least one preprocessing device, such as at least one of an amplifier, an analogue/digital converter, an electrical filter and a Fourier transformation.

The term “broadband detector” as used herein is a broad term and is to be given its ordinary and customary meaning to a person of ordinary skill in the art and is not to be limited to a special or customized meaning. The term specifically may refer, without limitation, to at least one detector in the above-mentioned sense which is configured for detecting light in more than one of the infrared, the visible and the ultraviolet spectral range. Specifically, the broadband detector may be configured for detecting detection light at least in a first portion of the visible spectral and in a second portion of the infrared spectral range, wherein the second portion may, preferably, adjoin the first portion; however, using a second portion that may be separated from the first portion may also be feasible. The broadband detector may be configured for detecting detection light from the object in a spectral range of 200 nm to 5 μm, preferably of 300 nm to 3 μm, more preferred of 400 nm to 2.5 μm.

The broadband detector may be configured for detecting light propagating from the object to the spectrometer device or more specifically to the detector of the spectrometer device, which, according to the above-mentioned nomenclature, is referred to as “detection light”. Thus, specifically, the broadband detector may be or may comprise at least one optical detector. The optical detector may be configured for determining at least one optical parameter, such as an intensity and/or a power of light by which at least one sensitive area of the broadband detector is irradiated. More specifically, the optical detector may comprise at least one photosensitive element and/or at least one optical sensor, such as at least one of a photodiode, a photocell, a photosensitive resistor, a phototransistor, a thermophile sensor, a photoacoustic sensor, a pyroelectric sensor, a photomultiplier and a bolometer. The broadband detector, thus, may be configured for generating at least one detector signal, more specifically at least one electrical detector signal, in the above-mentioned sense, providing information on at least one optical parameter, such as the power and/or intensity of light by which the broadband detector or a sensitive area of the broadband detector is illuminated.

The broadband detector may comprise one single optically sensitive element or area or a plurality of optically sensitive elements or areas. Specifically, the broadband detector may be or may comprise at least one detector array, more specifically an array of photosensitive elements, as will be outlined in further detail below. Each of the photosensitive elements may comprise at least a photosensitive area which may be adapted for generating an electrical signal depending on the intensity of the incident light, wherein the electrical signal may, in particular, be provided to the evaluation unit, as will be outlined in further detail below.

The photosensitive area as comprised by each of the optically sensitive elements may, especially, be a single, uniform photosensitive area which is configured for receiving the incident light which impinges on the individual optically sensitive elements. However, other arrangements of the optically sensitive elements may also be conceivable.

The array of optically sensitive elements may be designed to generate detector signals, preferably electronic signals, associated with the intensity of the incident light which impinges on the individual optically sensitive elements. The detector signal may be an analogue and/or a digital signal. The electronic signals for adjacent pixelated sensors can, accordingly, be generated simultaneously or else in a temporally successive manner. By way of example, during a row scan or line scan, it is possible to generate a sequence of electronic signals which correspond to the series of the individual optically sensitive elements which are arranged in a line. In addition, the individual optically sensitive elements may, preferably, be active pixel sensors which may be adapted to amplify the electronic signals prior to providing it to the evaluation unit. For this purpose, the broadband detector may comprise one or more signal processing devices, such as one or more filters and/or analogue-digital-converters for processing and/or preprocessing the electronic signals.

In case the broadband detector comprises an array of optically sensitive elements, the broadband detector, as an example, may be selected from any known pixel sensor, in particular, from a pixelated organic camera element, preferably, a pixelated organic camera chip, or from a pixelated inorganic camera element, preferably, a pixelated inorganic camera chip, more preferably from a CCD chip or a CMOS chip, which are, commonly, used in various cameras nowadays. As an alternative, the broadband detector generally may be or comprise a photoconductor, in particular an inorganic photoconductor, especially PbS, PbSe, InSb, or HgCdTe. As a further alternative, it may be or comprise a photodiode, especially a photodiode comprising at least one of Si, Ge, InGaAs, or ext. InGaAs. As a still further alternative, it may be or comprise at least one of pyroelectric, bolometer or thermophile detector elements. Thus, a camera chip having a matrix of 1×N pixels or of M×N pixels may be used here, wherein, as an example, M may be <10 and N may be in the range from 1 to 50, preferably from 2 to 20, more preferred from 5 to 10. Further, a monochrome camera element, preferably a monochrome camera chip, may be used, wherein the monochrome camera element may be differently selected for each optically sensitive element, especially, in accordance with the varying wavelength along the series of the optical sensors.

Thus, the array may be adapted to provide a plurality of the electrical signals which may be generated by the photosensitive areas of the optically sensitive elements comprised by the array. The electrical signals as provided by the array of the spectrometer device may be forwarded to the evaluation unit.

The term “primary detector signal” as used herein is a broad term and is to be given its ordinary and customary meaning to a person of ordinary skill in the art and is not to be limited to a special or customized meaning. The term specifically may refer, without limitation, to at least one detector signal in above-mentioned sense, which is generated by the broadband detector upon detecting the detection light in the spectral range of the primary light.

Similarly, the term “secondary detector signal” as used herein is a broad term and is to be given its ordinary and customary meaning to a person of ordinary skill in the art and is not to be limited to a special or customized meaning. The term specifically may refer, without limitation, to at least one detector signal in above-mentioned sense, which is generated by the broadband detector upon detecting the detection light in the spectral range of the secondary light.

The broadband detector may comprise a plurality of detector elements, such as the plurality of optically sensitive elements as outlined above, for detecting detection light in the spectral range of the primary light and the secondary light. For example, the broadband detector may comprise a pixelated broadband detector comprising a plurality of optically sensitive pixels or elements, as described in detail above. For example, the broadband detector may comprise at least one first detector element for detecting the detection light in the spectral range of the primary light and at least one second detector element for detecting the detection light in the spectral range of the secondary light. Specifically, the first detector element may be configured for generating the primary detector signal upon detecting the detection light in the spectral range of the primary light. The second detector element may be configured for generating the secondary detector signal upon detecting the detection light in the spectral range of the secondary light. Each detector element may comprise a photosensitive material selected from at least one of PbS, PbSe, InSb, or HgCdTe. The detector elements of the plurality of detector element may comprise the same photosensitive material or, alternatively, different photosensitive materials. Different materials of the detector elements may specifically be used in case different sensitivities in different wavelength ranges and/or different use cases are envisaged by different detector elements.

Alternatively, the broadband detector may be a single detector comprising a photosensitive material selected from at least one of PbS, PbSe, InSb, or HgCdTe. As a further alternative, the broadband detector may be a single detector comprising a photodiode, especially a photodiode having at least one of Si, Ge, InGaAs, or ext. InGaAs.

The spectrometer device may further comprise at least one driving unit for electrically driving the light source. The term “to drive” as used herein is a broad term and is to be given its ordinary and customary meaning to a person of ordinary skill in the art and is not to be limited to a special or customized meaning. The term specifically may refer, without limitation, to the process of providing one or both of at least one control parameter and/or electrical power to another device. Consequently, the term “driving unit” as used herein is a broad term and is to be given its ordinary and customary meaning to a person of ordinary skill in the art and is not to be limited to a special or customized meaning. The term specifically may refer, without limitation, to an arbitrary device or a combination of devices configured for providing one or both of at least one control parameter and/or electrical power to another device, such as, in the present case, to the at least one light source. For example, the driving unit specifically may be configured for at least one of measuring and controlling one or more electrical parameters of an electrical power provided to the light source, specifically to the at least one light-emitting diode. As an example, the driving unit may be configured for providing an electrical current to the LED, specifically for controlling an electrical current through the LED. Therein, as an example, the driving unit may be configured for adapting and measuring a voltage provided to the LED, the voltage being required for achieving a specific electrical current through the LED. The driving unit specifically may comprise one or more of: a current source, a voltage source, a current measurement device, such as an Ampère-meter, a voltage measurement device, such as a Volt-meter, a power measurement device. Specifically, the driving unit may comprise at least one current source for providing at least one predetermined current to the LED, wherein the current source specifically may be configured for adjusting or controlling a voltage applied to the LED in order to generate the predetermined current. The driving unit, as an example, may comprise one or more electrical components, such as integrated circuits, for driving the light source. The driving unit may fully or partially be integrated into the light source or may be separated from the light source.

The driving unit may be configured for driving the light-emitting diode with at least one driving frequency. The term “driving frequency” as used herein is a broad term and is to be given its ordinary and customary meaning to a person of ordinary skill in the art and is not to be limited to a special or customized meaning. The term specifically may refer, without limitation, to a quantitative measure of a number of driving repetitions of the light source in a unit of time. Specifically, the driving frequency may indicate a number of driving repetitions of the light source per second. The driving of the light source, i.e. the process of providing one or both of at least one control parameter and/or electrical power to the light source, with a first value causing the light source to emit light and with a second value causing the light source not to emit light may be referred to a single driving repetition.

Further, the driving frequency may exceed an inverse of a time constant t of the luminescent material. The term “time constant”, as used herein, is a broad term and is to be given its ordinary and customary meaning to a person of ordinary skill in the art and is not to be limited to a special or customized meaning. The term specifically may refer, without limitation, to a typical time interval describing a reorganization of the states of equilibrium, particularly of the luminescent material, when changing the at least one operating parameter. The time constant τ may describe a delay that occurs between the absorption of the at least one primary photon by the luminescent material and the emission of the at least one secondary photon by the luminescent material. This delay may be characterized by the so-called “characteristic time constant” τ, also referred to as the “time constant”, the “decay time” or the “saturation time”. When used in the context of processes in which a rate or probability of a process, such as emission of a photon, is proportional to the population of one or more states or process states, the population typically changes exponentially. The time constant τ, in these processes, may determine the 1/e-time of the process. For the luminescent material or converter, specifically for the phosphor, two different time constants may occur. Firstly, a first time constant may describe the typical time for reaching a saturation of the emission of converted light, such as the “growth constant”, which may depend on the intensity of the pump light. Secondly, a second time constant may describe the typical time of an afterglow of the luminescent material or converter, such as the “decay constant” or “decay”. The driving frequency may specifically exceed an inverse of the decay constant of the luminescent material. Further, the evaluation unit may be configured for differentiating between the primary detector signal and the secondary detector signal by demodulation, such as by using a Fourier transform, in particular a fast Fourier transform. Thus, the spectrometer device may be configured for pulse duration modulation of the light source by using the driving unit.

As outlined above, the spectrometer device comprises at least one evaluation unit for evaluating the primary detector signal and the secondary detector signal generated by the broadband detector. The term “to evaluate”, as used herein, is a broad term and is to be given its ordinary and customary meaning to a person of ordinary skill in the art and is not to be limited to a special or customized meaning. The term specifically may refer, without limitation, to the process of processing at least one first item of information in order to generate at least one second item of information thereby. Consequently, the term “evaluation unit”, as used herein, is a broad term and is to be given its ordinary and customary meaning to a person of ordinary skill in the art and is not to be limited to a special or customized meaning. The term specifically may refer, without limitation, to an arbitrary device or a combination of devices configured to evaluate or process at least one first item of information, in order to generate at least one second item of information thereof. Thus, specifically, the evaluation unit may be configured for processing at least one input signal and to generate at least one output signal thereof. The at least one input signal, as an example, may comprise at least one primary detector signal and at least one secondary detector signal provided directly or indirectly by the broadband detector.

As an example, the evaluation unit may be or may comprise one or more integrated circuits, such as one or more application-specific integrated circuits (ASICs), and/or one or more data processing devices, such as one or more of computers, digital signal processors (DSP), field programmable gate arrays (FPGA) preferably one or more microcomputers and/or microcontrollers. Additional components may be comprised, such as one or more preprocessing devices and/or data acquisition devices, such as one or more devices for receiving and/or preprocessing of the detector signals, such as one or more AD-converters and/or one or more filters. Further, the evaluation unit may comprise one or more data storage devices. Further, the evaluation unit may comprise one or more interfaces, such as one or more wireless interfaces and/or one or more wire-bound interfaces.

The evaluation unit may be adapted to execute at least one computer program, such as at least one computer program performing or supporting the step of generating the items of information. As an example, one or more algorithms may be implemented which, by using the primary and the secondary detector signals as input variables, may perform a predetermined transformation for determining temperature information on the light source and for deriving the spectroscopic information on the object, such as for deriving at least one spectroscopic information describing at least one property of the object, whereby a temperature prevailing at the light source may be taken into account. For this purpose, the evaluation unit may, particularly, comprise at least one data processing device, also referred to as a processor, in particular an electronic data processing device, which can be designed to generate the desired information by evaluating the primary and the secondary detector signals. The evaluation unit may use an arbitrary process for generating the required information, such as by calculation and/or using at least one stored and/or known relationship. The evaluation unit specifically may be configured for performing at least one digital signal processing (DSP) technique on the primary detector signal or any secondary detector signal derived thereof, in particular at least one Fourier transformation. Additionally or alternatively, the evaluation unit may be configured for performing one or more further digital signal processing techniques on the primary detector signal or any secondary detector signal derived thereof, e.g. windowing, filtering, Goertzel algorithm, cross-correlation and autocorrelation. Besides the primary and secondary detector signals, one or a plurality of further parameters and/or items of information can influence said relationship. The relationship can be determined or determinable empirically, analytically or else semi-empirically. As an example, the relationship may comprise at least one of a model or calibration curve, at least one set of calibration curves, at least one function or a combination of the possibilities mentioned. One or a plurality of calibration curves can be stored for example in the form of a set of values and the associated function values thereof, for example in a data storage device and/or a table. Alternatively or additionally, however, the at least one calibration curve can also be stored for example in parameterized form and/or as a functional equation. Separate relationships for processing the primary and secondary detector signals into the items of information may be used. Alternatively, at least one combined relationship for processing the primary and secondary detector signals is feasible. Various possibilities are conceivable and can also be combined.

The evaluation unit is configured for
evaluating the primary detector signal and the secondary detector signal generated by the broadband detector,
determining temperature information on the light source from one of the primary detector signal or the secondary detector signal, and
deriving the spectroscopic information on the object from the other of the primary detector signal or the secondary detector signal by taking into account the temperature information on the light source.

The term “temperature information” as used herein is a broad term and is to be given its ordinary and customary meaning to a person of ordinary skill in the art and is not to be limited to a special or customized meaning. The term specifically may refer, without limitation, to a particular item of information, e.g. on at least one body, characterizing at least one property of the body which is related to a temperature of the body, more specifically at least one item of information characterizing, e.g. qualifying and/or quantifying, at least one of a body temperature, a surface temperature, a temperature in a vicinity of the body. Specifically, the intensity information may correspond to or be derived from the signal intensity, specifically the electrical signal, recorded by the spectrometer device with respect to a wavelength or a range of wavelengths of the spectrum.

For the purposes of the present invention, the body may be or comprise the at least one light source which used for generating the illumination light for illuminating the object. Accordingly, the light sources comprises the at least one light-emitting diode and the at least one luminescent material for light-conversion of the primary light generated by the light-emitting diode into the secondary light. As already indicated above, the luminescent material and the light-emitting diode may, in general, be thermally coupled during the operation of the light source. Owing to this kind of thermal coupling, a single temperature can be assigned to both the light-emitting diode and the luminescent material as comprised by the light source. Accordingly, one of the spectra or a portion thereof can be used for determining the temperature information, such as the single temperature, which is assigned to the light source. Thereafter, the single temperature of the light source which has been determined before, is determined at the same point in time, or will consecutively be determined in this fashion can be taken into account when the spectroscopic information on the object may be derived from the other spectrum. The term “taking into account” or any grammatical variation thereof as used herein is a broad term and is to be given its ordinary and customary meaning to a person of ordinary skill in the art and is not to be limited to a special or customized meaning. The term specifically may refer, without limitation, to a process of using at least one first item of information in order to modify at least one second item of information, especially in order to determine the at least one second item of information by considering at least one kind of influence, such as a temperature, as expressed by the at least one first item of information, on the at least one second item of information.

In a particularly preferred embodiment, the temperature information on the light source can be determined from the primary detector signal, while the spectroscopic information on the object can be derived from the secondary detector signal by taking into account the temperature information on the light source as determined from the primary detector signal. However, the temperature information on the light source can, alternatively or in addition, be determined from the secondary detector signal, while the spectroscopic information on the object can be derived from the primary detector signal by taking into account the temperature information on the light source as determined from the secondary detector signal. By way of example, a broadband detector as described elsewhere herein can be used for, simultaneously, detecting the primary detector signal and the secondary detector signal, which may, subsequently, be used for the purpose as indicated above. As a further example, the broadband detector may comprise a plurality of detector elements, wherein at least one particular detector element may be configured for determining the temperature information on the light source, while at least one further detector element may be configured for deriving the spectroscopic information on the object. However, further examples are conceivable.

The spectroscopic information on the object may comprise at least one of a volume spectroscopic information on the object and a surface spectroscopic information on the object. Specifically, a penetration depth of the illumination light into the object may be dependent on the object itself and/or on the spectral range of the primary light or the secondary light as used for deriving the spectroscopic information. For example, the object to be analyzed by the spectrometer device may comprise a skin of a user. In this example, the evaluation unit may specifically be configured for evaluating the primary detector signal generated by the broadband detector and for deriving a volume spectroscopic information on the object. Further, the evaluation unit may be configured for evaluating the secondary detector signal generated by the broadband detector and for determining temperature information about the light source that is employed in deriving the spectroscopic information on the object. In this fashion, a heat-up of both the LED and the luminescent material during an operation of the light source can be determined and used for correcting the spectroscopic information on the object. The term “correcting”, as used herein, is a broad term and is to be given its ordinary and customary meaning to a person of ordinary skill in the art and is not to be limited to a special or customized meaning. The term specifically may refer, without limitation, to a process of using at least one first item of information in order to modify at least one second item of information thereby, especially in order to compensate at least one kind of influence, such as a temperature, as expressed by the at least one first item of information, on the at least one second item of information. For example, the object may contain water with strong absorption in the NIR spectral range, such as in a spectral range with wavelength of 1300 nm and higher. Thus, having the spectral range of the secondary light located in this spectral range, it may be possible to derive surface spectroscopic information on the object by evaluating the secondary detector signal. Further, the primary detector signal may be used to determine a temperature from a known temperature dependence in a further spectral range, wherein the temperature estimated in this manner can be used for compensating the influence of the heat-up of the light source during its operation. By way of example, the intensity of the pump LED can be used for such a purpose, in particular since the intensity of the pump LED, at a constant operating current, depends from an efficiency of the pump LED and, thus, from a temperature of the pump LED. As a further example, a spectral shift of the pump LED can be monitored as a function of temperature of the pump LED, especially by observing a plurality of wavelengths within a spectral range of 420 nm to 460 nm. However, various further examples are conceivable.

It may be possible to generate the primary and secondary detector signals in these wavelength range by using the plurality of detector elements, for example at least one detector element comprising Si for a wavelength around 940 nm, and at least one further detector element comprising PbS for a wavelength of 1500 to 2500 nm. Alternatively, a single broadband detector, specifically a single broadband detector comprising PbS, may be used to detect the detection light in both wavelength ranges. As a further alternative, a Si photodiode may be used as a single broadband detector, specifically for detecting primary light around 440 nm and secondary light around 1100 nm. Since the pump LED may be faster than the luminescent material, a pulse form applied to the pump LED may be used such that a frequency domain information obtained from a fast Fourier transform may provide both spectroscopic information from the primary detector signal and the second detector signal with the single broadband detector.

The spectrometer device may further comprise at least one wavelength-selective element. The term “wavelength selective element” as used herein is a broad term and is to be given its ordinary and customary meaning to a person of ordinary skill in the art and is not to be limited to a special or customized meaning. The term specifically may refer, without limitation, to an arbitrary optical element which interacts with differing spectral portions of incident light in a different manner, e.g. by having at least one wavelength-dependent optical property, such as at least one wavelength-dependent optical property selected from the list consisting of a degree of reflection, a direction of reflection, a degree of refraction, a direction of refraction, an absorption, a transmission, an index of refraction.

The wavelength-selective element may be arranged such that the broadband detector generates the at least one primary detector signal upon detecting the detection light in the spectral range of the primary light and the at least one secondary detector signal upon detecting the detection light in the spectral range of the secondary light.

The wavelength selection by the at least one wavelength-selective element may take place in the at least one beam path of the illumination light, thereby selecting and/or modifying a wavelength of the illumination of the object, and/or in the detection beam path of the detection light, thereby selecting and/or modifying a wavelength of detection, e.g. for the broadband detector in general and/or for each of the detector elements. The wavelength-selective element may comprise at least one of a wavelength-selective element disposed in a beam path of the illumination light or a wavelength-selective element disposed in a beam path of the detection light.

The wavelength-selective element may be selected from at least one of a tunable wavelength-selective element or a wavelength-selective element having a fixed transmission spectrum. The wavelength-selective element having a fixed transmission spectrum may comprise at least one filter element, specifically at least one absorption filter element, more specifically a bandpass filter element. The tunable wavelength-selective element may comprise at least one tunable interferometer, specifically at least one of a MEMS Fabry-Pérot interferometer and a MEMS Michelson interferometer.

For example, the wavelength-selective element may be arranged in the detection beam path of the detection light. The wavelength-selective element may be configured for guiding the detection light in the spectral range of the primary light on the first detector element comprised by the broadband detector such that the broadband detector detects the detection light in the spectral range of the primary light and, thus, generates the primary detector signal. The wavelength-selective element may further be configured for guiding the detection light in the spectral range of the secondary light on the second detector element comprised by the broadband detector such that the broadband detector detects the detection light in the spectral range of the secondary light and, thus, generates the secondary detector signal. Alternatively, the broadband detector may be the single detector, as outlined above, and the wavelength-selective element may be a tunable wavelength-selective element, such that the spectral range to be detected by the broadband detector can be adjusted.

In a further aspect of the present invention, a method of obtaining spectroscopic information on at least one object is disclosed.

The method comprises the following steps that may be performed in the given order. However, a different order may also be possible. In particular, one, more than one or even all of the meth-od steps may be performed once or repeatedly. Further, the method steps may be performed successively or, alternatively, one or more of the method steps may be performed in a timely overlapping fashion or even in a parallel fashion and/or in a combined fashion. The method may further comprise additional method steps that are not listed.

The method comprises:
a) providing at least one spectrometer device according to the present invention, such as according to any one of the embodiment disclosed above and/or according to any one of the embodiment disclosed in further detail below;
b) illuminating the object with illumination light generated by the light source, the light source comprising at least one light-emitting diode and at least one luminescent material for light-conversion of primary light generated by the light-emitting diode into secondary light, wherein the illumination light at least partially comprises the primary light and the secondary light;
c) detecting detection light from the object in a spectral range at least partially comprising the spectral ranges of the primary light and the secondary light, by using at least one broadband detector, wherein the broadband detector is configured for generating at least one primary detector signal upon detecting the detection light in the spectral range of the primary light, wherein the broadband detector is configured for generating at least one secondary detector signal upon detecting the detection light in the spectral range of the secondary light; and
d) evaluating the primary detector signal and the secondary detector signal generated by the broadband detector by using the evaluation unit, determining temperature information on the light source from one of the primary detector signal or the secondary detector signal, and deriving the spectroscopic information on the object from the other of the primary detector signal or the secondary detector signal by taking into account the temperature information on the light source.

Specifically, the method may comprise using the spectrometer device according to the present invention, such as according to any one of the embodiment disclosed above and/or according to any one of the embodiment disclosed in further detail below. Thus, for possible embodiment of the spectrometer device and/or for definitions of terms, reference is made to the description of the spectrometer device as outlined above.

Step d) may comprise determining the temperature information on the light source from the primary detector signal and the spectroscopic information on the object from the secondary detector signal by taking into account the temperature information on the light source as determined from the primary detector signal. Specifically, the spectroscopic information on the object may comprise at least one of a volume spectroscopic information on the object and a surface spectroscopic information on the object.

Alternatively or in addition, step d) may comprise determining the temperature information on the light source from the secondary detector signal and the spectroscopic information on the object from the primary detector signal by taking into account the temperature information on the light source as determined from the secondary detector signal. Again, the spectroscopic information on the object may comprise at least one of a volume spectroscopic information on the object and a surface spectroscopic information on the object.

The spectrometer device may further comprise at least one driving unit for electrically driving the light source. The method may comprise, specifically in step b), driving the light-emitting diode with at least one driving frequency by using the driving unit. The driving frequency may be higher than an inverse of a time constant t of the luminescent material. The evaluating in step d) may comprise differentiating between the primary detector signal and the secondary detector signal by demodulation, such as by using a Fourier transform, in particular a fast Fourier transform.

The method may be at least partially computer-implemented, specifically at least step d). Referring to the computer-implemented aspects of the invention, one or more of the method steps or even all of the method steps of the method according to one or more of the embodiments disclosed herein may be performed, supported or assisted by using a computer or computer network. Thus, generally, any of the method steps including provision and/or manipulation of data may be performed by using a computer or computer network. Generally, these method steps may include any of the method steps, typically except for method steps requiring manual work, such as providing the spectrometer device and/or providing the object and/or certain aspects of performing the actual measurements.

In a further aspect of the present invention, a computer program is disclosed, comprising instructions which, when the program is executed by the spectrometer device according to the present invention, such as according to any one of the embodiment disclosed above and/or according to any one of the embodiment disclosed in further detail below, cause the spectrometer device to perform at least steps b) to d) of the method according to the present invention, such as according to any one of the embodiment disclosed above and/or according to any one of the embodiment disclosed in further detail below.

In a further aspect of the present invention, a computer-readable storage medium, specifically a non-transient computer-readable medium, is disclosed, comprising instructions which, when the instructions are executed by the spectrometer device according to the present invention, such as according to any one of the embodiment disclosed above and/or according to any one of the embodiment disclosed in further detail below, cause the spectrometer device to perform at least steps b) to d) of the method according to the present invention, such as according to any one of the embodiment disclosed above and/or according to any one of the embodiment disclosed in further detail below.

As used herein, the term “computer-readable storage medium” specifically may refer to non-transitory data storage means, such as a hardware storage medium having stored thereon computer-executable instructions. The computer-readable storage medium specifically may be or may comprise a storage medium such as a random-access memory (RAM) and/or a read-only memory (ROM).

The spectrometer device and the method according to the present invention, in one or more of the above-mentioned embodiments and/or in one or more of the embodiments described in further detail below, provide a large number of advantages over known devices and methods of similar kind. The spectrometer device comprising the broadband detector may offer the possibility to use both the primary light and the secondary light for determining temperature information on the light source and, in addition, deriving spectroscopic information on the object by taking into account the temperature information, specifically by using the pump LED with shorter emission wavelengths and the luminescent material with an emission spectrum at longer wavelengths to select and/or extend spectral emission ranges. In this manner, a heat-up of both the LED and the luminescent material during an operation of the light source can be estimated and used for correcting the spectroscopic information on the object.

In order to detect radiation in both wavelength ranges, the spectrometer device comprises the broadband detector, specifically being embodied by two or more individual detector elements or a single broadband detector, which is sensitive to both wavelength regimes of the primary light and the secondary light, specifically to both the pump wavelength range of the LED as well as the converted wavelength range of the luminescent material. When using a single broadband detector for detecting both radiations, the pulse duration modulation of the light source may allow differentiating between the primary detector signal and the secondary detector signal.

In a particularly preferred embodiment, the pump LED can be modulated by using a pulse train, specifically by using a driving unit as disclosed elsewhere herein in more detail. The term “pulse train” as used herein is a broad term and is to be given its ordinary and customary meaning to a person of ordinary skill in the art and is not to be limited to a special or customized meaning. The term specifically may refer, without limitation, to a consecutive sequence of pulses, wherein the sequence has a high frequency for individual pulses but a lower frequency for pulse packages, especially in order to generate an excitation of at least one material being impinged by the pulse train. In other words, the high frequency sequence of the individual pulses can be modulated by the lower frequency of the pulse packages, which can be expressed by a modulation frequency f₁. For a purpose of providing further information about the modulation frequency f₁, a decay which, typically, occurs between the absorption of the at least one primary photon by the luminescent material and the emission of the at least one secondary photon by the luminescent material can be taken into account. This delay may be characterized by the so-called “characteristic time constant” τ, also referred to as the “time constant”, the “decay time” or the “saturation time”. As generally known to the skilled person, the term “time constant”, as used herein, is a broad term and is to be given its ordinary and customary meaning to a person of ordinary skill in the art and is not to be limited to a special or customized meaning. When used in the context of processes in which a rate or probability of a process, such as emission of a photon, is proportional to the population of one or more states or process states, the population typically changes exponentially. The time constant τ, in these processes, may determine the 1/e-time of the process. For the luminescent material or converter, specifically for the phosphor, two different time constants may occur. Firstly, a first time constant may describe the typical time for reaching a saturation of the emission of converted light. Secondly, a second time constant may describe the typical time of an afterglow of the luminescent material or converter.

Typical time constants of phosphor converters are in the range of 0.1 ms to <10 ms. The time constants typically differ between different phosphor LEDs and/or between different types of the luminescent material or phosphor. Typically, shorted wavelengths emitting phosphor exhibit smaller time constants. Additionally, a decay time constant τ_{d} and a growth time constant τ_{g} may depend on the wavelength. These time constants are, typically, extracted from a step response of the optical signal by applying or shutting off the forward current, respectively.

After turning off the forward current, the signal or emission typically decays according to equation (1):

$$S ( t ) = {S}_{max} {e}^{- ( t - {t}_{0} ) / {τ}_{d}} + {S}_{0} . \qquad ( 1 )$$

After turning on the forward current, the signal or emission typically grows according to equation (2):

$$S ( t ) = {S}_{max} ( 1 - {e}^{- ( t - {t}_{0} ) / {τ}_{g}} ) + {S}_{0} . \qquad ( 2 )$$

For both equations (1) and (2), S₀ is the optical signal level at t₀, when the forward current is applied/shut off. Sₘₐₓ is the reached optical signal level as t>>5.

In particular, by using the growth time constant τ_{g} and the τ_{d} denotes a decay time constant, the modulation frequency f₁ can, especially, be expressed by equation (3) as

$${f}_{1} ≫ \frac{1}{max ( {τ}_{g} , {τ}_{d} )} \qquad ( 3 )$$

An exemplary embodiment of a pulse train is described and illustrated below.

With particular regard to the present invention, the pulse train allows, concurrently providing primary light having the high frequency of the individual pulses as generated by the pump LED and secondary light having the lower modulation frequency f₁ of the pulse packages, wherein the lower modulation frequency f₁ of the pulse packages is selected in order to allow the luminescent material or converter, specifically the phosphor, to follow the excitation by the pulse packages as provided by the pulse train. When using a single broadband detector for detecting both radiations, frequency multiplexing of the combined detector signal as generated by the single broadband detector allows differentiating between the primary detector signal, i.e. the pump-signal as provided by the LED, and the secondary detector signal, i.e. the converter signal as provided by the luminescent material, specifically the phosphor, within the combined detector signal as generated by the single broadband detector. In this manner, the different type of information can be retrieved from the combined detector signal as generated by the single broadband detector and, subsequently, used for the purposes of the present invention, i.e. determining the temperature information on the light source and deriving the spectroscopic information on the object by taking into account the temperature information on the light source.

As used herein, the terms “have”, “comprise” or “include” or any arbitrary grammatical variations thereof are used in a non-exclusive way. Thus, these terms may both refer to a situation in which, besides the feature introduced by these terms, no further features are present in the entity described in this context and to a situation in which one or more further features are present. As an example, the expressions “A has B”, “A comprises B” and “A includes B” may both refer to a situation in which, besides B, no other element is present in A (i.e. a situation in which A solely and exclusively consists of B) and to a situation in which, besides B, one or more further elements are present in entity A, such as element C, elements C and D or even further elements.

Further, it shall be noted that the terms “at least one”, “one or more” or similar expressions indicating that a feature or element may be present once or more than once typically are used only once when introducing the respective feature or element. In most cases, when referring to the respective feature or element, the expressions “at least one” or “one or more” are not repeated, notwithstanding the fact that the respective feature or element may be present once or more than once.

Further, as used herein, the terms “preferably”, “more preferably”, “particularly”, “more particularly”, “specifically”. “more specifically” or similar terms are used in conjunction with optional features, without restricting alternative possibilities. Thus, features introduced by these terms are optional features and are not intended to restrict the scope of the claims in any way. The invention may, as the skilled person will recognize, be performed by using alternative features. Similarly, features introduced by “in an embodiment of the invention” or similar expressions are intended to be optional features, without any restriction regarding alternative embodiments of the invention, without any restrictions regarding the scope of the invention and without any restriction regarding the possibility of combining the features introduced in such way with other optional or non-optional features of the invention.

Summarizing and without excluding further possible embodiments, the following embodiments may be envisaged:
Embodiment 1: A spectrometer device for obtaining spectroscopic information on at least one object, the spectrometer device comprising:
   i. at least one light source for generating illumination light for illuminating the object, the light source comprising at least one light-emitting diode and at least one luminescent material for light-conversion of primary light generated by the light-emitting diode into secondary light, wherein the illumination light at least partially comprises the primary light and the secondary light;
   ii. at least one broadband detector for detecting detection light from the object in a spectral range at least partially comprising the spectral ranges of the primary light and the secondary light, wherein the broadband detector is configured for generating at least one primary detector signal upon detecting the detection light in the spectral range of the primary light, wherein the broadband detector is further configured for generating at least one secondary detector signal upon detecting the detection light in the spectral range of the secondary light; and
   iii. at least one evaluation unit for evaluating the primary detector signal and the secondary detector signal generated by the broadband detector, for determining temperature information on the light source from one of the primary detector signal or the secondary detector signal, and for deriving the spectroscopic information on the object from the other of the primary detector signal or the secondary detector signal by taking into account the temperature information on the light source.
Embodiment 2: The spectrometer device according to the preceding embodiment, wherein the evaluation unit is configured for determining the temperature information on the light source from the primary detector signal and the spectroscopic information on the object from the secondary detector signal by taking into account the temperature information on the light source as determined from the primary detector signal.
Embodiment 3: The spectrometer device according to any one of the preceding embodiments, wherein the evaluation unit is configured for determining the temperature information on the light source from the secondary detector signal and the spectroscopic information on the object from the primary detector signal by taking into account the temperature information on the light source as determined from the secondary detector signal.
Embodiment 4: The spectrometer device according to any one of the preceding embodiments, wherein the light-emitting diode and the luminescent material are thermally coupled.
Embodiment 5: The spectrometer device according to the preceding embodiment, wherein a temperature difference of 0.1 K to 5 K, in particular of 0.1 K to 1 K, specifically of 0.1 K to 0.5 K, exists between the light-emitting diode and the luminescent material during operation of the light source.
Embodiment 6: The spectrometer device according to any one of the preceding embodiments, wherein the broadband detector is configured for detecting detection light from the object in a spectral range of 200 nm to 5 μm, preferably of 300 nm to 3 μm, more preferred of 400 nm to 2.5 μm.
Embodiment 7: The spectrometer device according to any one of the preceding embodiments, wherein the broadband detector comprises a plurality of detector elements for detecting detection light in the spectral ranges of the primary light and the secondary light.
Embodiment 8: The spectrometer device according to the preceding embodiment, wherein each detector element comprises a photosensitive material selected from at least one of PbS, PbSe, InSb, or HgCdTe.
Embodiment 9: The spectrometer device according to any one of the two preceding embodiments, wherein each detector element comprises a photodiode, especially a photodiode comprising at least one of Si, Ge, InGaAs, or ext. InGaAs.
Embodiment 10: The spectrometer device according to any one of the preceding embodiments, wherein the broadband detector is a single detector comprising a photosensitive material selected from at least one of PbS, PbSe, InSb, or HgCdTe.
Embodiment 11: The spectrometer device according to any one of the preceding embodiments, wherein the broadband detector is a single detector comprising a photodiode, especially a photodiode comprising at least one of Si, Ge, InGaAs, or ext. InGaAs.
Embodiment 12: The spectrometer device according to the preceding embodiment, further comprising at least one driving unit for electrically driving the light source, wherein the driving unit is configured for driving the light-emitting diode with at least one driving frequency, wherein the driving frequency exceeds an inverse of a time constant T of the luminescent material.
Embodiment 13: The spectrometer device according to the preceding embodiment, wherein the evaluation unit is configured for differentiating between the primary detector signal and the secondary detector signal by demodulation, such as by using a Fourier transform, in particular a fast Fourier transform.
Embodiment 14: The spectrometer device according to any one of the preceding embodiments, wherein the illumination light comprises those parts of the primary light generated by the light-emitting diode which are not converted into the secondary light by the luminescent material and the secondary light.
Embodiment 15: The spectrometer device according to any one of the preceding embodiments, wherein the primary light is at least partially located in a spectral range of 380 nm to 1000 nm, specifically in a spectral range of 420 nm to 940 nm, more specifically in a spectral range of 420 nm to 830 nm, more specifically in a spectral range of 440 nm to 830 nm.
Embodiment 16: The spectrometer device according to the preceding embodiment, wherein the primary light which is not converted into the secondary light by the luminescent material is at least partially located in a spectral range of 380 nm to 1000 nm, specifically in a spectral range of 420 nm to 940 nm, more specifically in a spectral range of 420 nm to 830 nm, more specifically in a spectral range of 440 nm to 830 nm.
Embodiment 17: The spectrometer device according to any one of the preceding embodiments, wherein the secondary light is at least partially located in a spectral range of 1 μm to 5 μm, specifically in a spectral range of 1.5 μm to 3 μm, more specifically in a spectral range of 1.5 μm to 2.5 μm.
Embodiment 18: The spectrometer device according to any one of the preceding embodiments, wherein the light source comprises a phosphor light-emitting diode.
Embodiment 19: The spectrometer device according to any one of the preceding embodiments, wherein the spectrometer device further comprises at least one wavelength-selective element, wherein the wavelength-selective element is arranged such that the broadband detector generates the at least one primary detector signal upon detecting the detection light in the spectral range of the primary light and the at least one secondary detector signal upon detecting the detection light in the spectral range of the secondary light.
Embodiment 20: The spectrometer device according to the preceding embodiment, the wavelength-selective element comprises at least one of a wavelength-selective element disposed in a beam path of the illumination light or a wavelength-selective element disposed in a beam path of the detection light.
Embodiment 21: The spectrometer device according to any one of the two preceding embodiments, wherein the wavelength-selective element is selected from at least one of a tunable wavelength-selective element or a wavelength-selective element having a fixed transmission spectrum.
Embodiment 22: The spectrometer device according to the preceding embodiment, wherein the wavelength-selective element having a fixed transmission spectrum comprises at least one filter element, specifically at least one absorption filter element, more specifically a bandpass filter element.
Embodiment 23: The spectrometer device according to any one of the two preceding embodiments, wherein the tunable wavelength-selective element comprises at least one tunable interferometer, specifically at least one of a MEMS Fabry-Pérot interferometer and a MEMS Michelson interferometer.
Embodiment 24: A method of obtaining spectroscopic information on at least one object, the method comprising:
   a) providing at least one spectrometer device according to any one of the preceding embodiments;
   b) illuminating the object with illumination light generated by the light source, the light source comprising at least one light-emitting diode and at least one luminescent material for light-conversion of primary light generated by the light-emitting diode into secondary light, wherein the illumination light at least partially comprises the primary light and the secondary light;
   c) detecting detection light from the object in a spectral range at least partially comprising the spectral ranges of the primary light and the secondary light, by using at least one broadband detector, wherein the broadband detector is configured for generating at least one primary detector signal upon detecting the detection light in the spectral range of the primary light, wherein the broadband detector is configured for generating at least one secondary detector signal upon detecting the detection light in the spectral range of the secondary light; and
   d) evaluating the primary detector signal and the secondary detector signal generated by the broadband detector by using the evaluation unit, determining temperature information on the light source from one of the primary detector signal or the secondary detector signal, and deriving the spectroscopic information on the object from the other of the primary detector signal or the secondary detector signal by taking into account the temperature information on the light source.
Embodiment 25: The method according to the preceding embodiment, wherein step d) comprises determining the temperature information on the light source from the primary detector signal and the spectroscopic information on the object from the secondary detector signal by taking into account the temperature information on the light source as determined from the primary detector signal.
Embodiment 26: The method according to any one of the preceding method embodiments, wherein step d) comprises determining the temperature information on the light source from the secondary detector signal and the spectroscopic information on the object from the primary detector signal by taking into account the temperature information on the light source as determined from the secondary detector signal.
Embodiment 27: The spectrometer device according to any one of the preceding embodiments, wherein the light-emitting diode and the luminescent material are thermally coupled.
Embodiment 28: The spectrometer device according to the preceding embodiment, wherein the thermal coupling provides a temperature difference of 0.1 K to 5 K, in particular of 0.1 K to 1 K, specifically of 0.1 K to 0.5 K, between the light-emitting diode and the luminescent material during operation of the light source.
Embodiment 29: The method according to any one of the preceding method embodiments, the spectrometer device further comprising at least one driving unit for electrically driving the light source, wherein the method comprises, specifically in step b), driving the light-emitting diode with at least one driving frequency by using the driving unit, wherein the driving frequency is higher than an inverse of a time constant T of the luminescent material.
Embodiment 30: The method according to the preceding embodiment, wherein the evaluating in step d) comprises differentiating between the primary detector signal and the secondary detector signal by demodulation, such as by using a Fourier transform, in particular a fast Fourier transform.
Embodiment 31: The method according to any one of the preceding method embodiments, wherein the method comprises, specifically in step b), using a pulse train having a high frequency for individual pulses generated by the light-emitting diode but a lower frequency for pulse packages applied to the luminescent material.
Embodiment 32: The method according to the preceding embodiment, wherein the differentiating between the primary detector signal and the secondary detector signal comprises, specifically in step c), frequency multiplexing of a combined detector signal as generated by a single broadband detector, wherein the combined detector signal comprises both the primary detector signal and the secondary detector signal.
Embodiment 33: The method according to anyone of the preceding method embodiments, wherein the method is at least partially computer-implemented, specifically at least step d).
Embodiment 34: A computer program comprising instructions which, when the program is executed by the spectrometer device according to any one of the preceding embodiments referring to a spectrometer device, cause the spectrometer device to perform at least steps b) to d) of the method according to any one of the preceding embodiments referring to a method.
Embodiment 35: A computer-readable storage medium, specifically a non-transient computer-readable medium, comprising instructions which, when the instructions are executed by the spectrometer device according to any one of the preceding embodiments referring to a spectrometer device, cause the spectrometer device to perform at least steps b) to d) of the method according to any one of the preceding embodiments referring to a method.

### SHORT DESCRIPTION OF THE FIGURES

Further optional features and embodiments will be disclosed in more detail in the subsequent description of embodiments, preferably in conjunction with the dependent claims. Therein, the respective optional features may be realized in an isolated fashion as well as in any arbitrary feasible combination, as the skilled person will realize. The scope of the invention is not restricted by the preferred embodiments. The embodiments are schematically depicted in the Figures. Therein, identical reference numbers in these Figures refer to identical or functionally comparable elements.

In the Figures:

FIG. 1 shows a schematic overview of an embodiment of a spectrometer device;

FIG. 2 shows a schematic cross-sectional view of an embodiment of a light source;

FIG. 3 shows a flow chart of an embodiment of a method of obtaining spectroscopic information on at least one object;

FIG. 4 shows a diagram of a spectral response of a broadband detector; and

FIG. 5 shows a diagram of a pulse duration modulation.

### DETAILED DESCRIPTION OF THE EMBODIMENTS

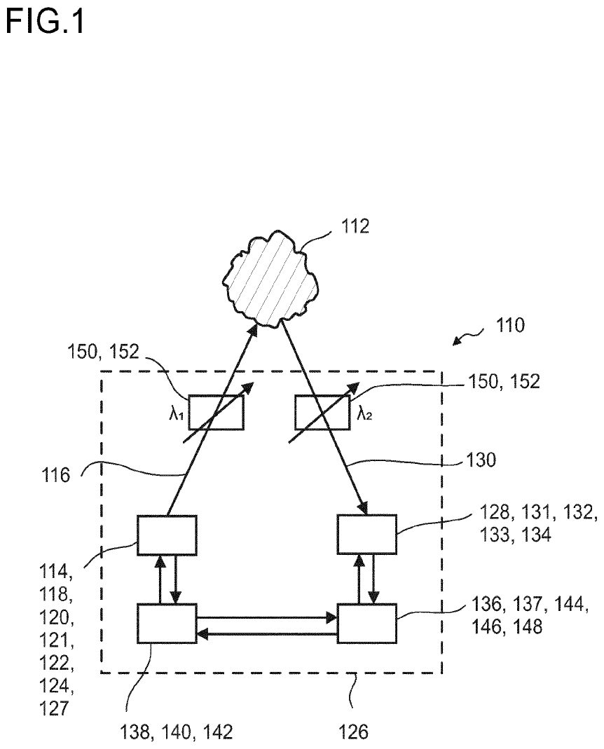

In FIG. 1, a schematic overview of a spectrometer device 110 for obtaining spectroscopic information on at least one object 112 is shown. The spectrometer device 110 may comprise a plurality of components as illustrated in FIG. 1. Possible components of the spectrometer device 110 and their interplay will be described in the following, specifically with reference to FIG. 1. The spectrometer device 110 comprises at least one light source 114 for generating illumination light 116 for illuminating the object 112. The light source 114 may be at least one of a tunable light source, a light source having at least one fixed emission wavelength and a broadband light source. The light source 114 specifically may be or may comprise at least one electrical light source. The light source 114 comprises at least one light-emitting diode 118 and at least one luminescent material 120 for light-conversion of primary light generated by the light-emitting diode 118 into secondary light. As an example, the light-emitting diode 118, may comprise one or more of: a light-emitting diode (LED) based on spontaneous emission of light, a light-emitting diode based on superluminescence (sLED), a laser diode (LLED).

The LED 118 may specifically comprise at least two layers of semiconductor material 121, wherein light may be generated at at least one interface between the at least two layers of semiconductor material 121, specifically due to a recombination of positive and negative electrical charges. The at least two layers of semiconductor material 121 may have differing electrical properties, such as at least one of the layers being an n-doped semiconductor material 121 and at least one of the layers being a p-doped semiconductor material 121. Thus, as an example, the LED 118 may comprise at least one pn-junction and/or at least one pin-set up. It shall be noted, however, that other device structures are feasible, too.

The light-emitting diode 118 may generate primary light, which may also be referred to as “pump light”. The primary light may subsequently be transformed into “secondary light”, such as by using light conversion, e.g. through one or more luminescent materials 120, such as phosphor materials. The at least one luminescent material 120, thus, may form at least one converter, also referred to as a light converter, transforming primary light into secondary light having different spectral properties as compared to the primary light. Specifically, a spectral width of the secondary light may be larger than a spectral width of the primary light, and/or a center of emission of the secondary light may be shifted, specifically red-shifted, compared to the primary light. Specifically, the at least one luminescent material 120 may have an absorption in the ultraviolet and/or blue spectral range and an emission in the near-infrared and/or infrared spectral range. The illumination light 116 at least partially comprises the primary light and the secondary light. Specifically, the illumination light 116 may comprise those parts of the primary light generated by the light-emitting diode 118 which are not converted into the secondary light by the luminescent material 120, e.g. due to conversion inefficiency of the luminescent material 120, and the secondary light.

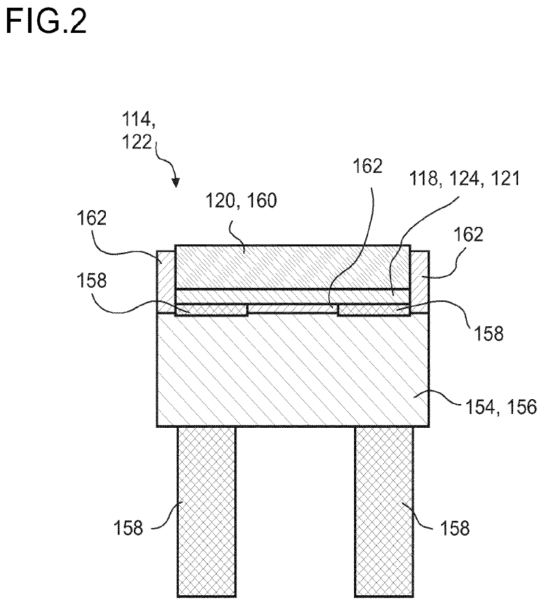

As indicated in FIG. 1, the light source 114 may specifically comprise a phosphor light-emitting diode 122, also referred to as phosphor LED 122. The phosphor LED 122 may be a combination of at least one light-emitting diode 118 configured for generating primary light or pump light, and at least one luminescent material 120, also referred to as a “phosphor”, configured for light-conversion of the primary light generated by the light-emitting diode 118. The phosphor LED 122 may form a packaged LED light source, including an LED die 124, e.g. a blue LED emitting blue pump light, as well as the phosphor, which, as an example, fully or partially coats the LED 118, which is, as an example, configured for converting the primary light or blue light into light having differing spectral properties, specifically into near-infrared light. FIG. 2 shows a more detailed view of the light source 114 embodied as a phosphor LED 122.

Generally, the light source 114 can be embodied in various ways. Thus, the light source 114 can, for example, be part of the spectrometer device 110 in a housing 126 of the spectrometer device 110, as illustrated in FIG. 1. Alternatively or additionally, however, the at least one light source 114 can also be arranged outside the housing 126, for example as a separate light source 114 (not shown). The light source 114 can be arranged separately from the object 112 and illuminate the object 112 from a distance, as indicated in FIG. 1. Thereby, the light-emitting diode 118 and the luminescent material 120 may, in general, be thermally coupled as indicated by reference sign 127. In other words, a temperature difference of 0.1 K to 5 K, in particular of 0.1 K to 1 K, specifically of 0.1 K to 0.5 K, may exist between the light-emitting diode 118 and the luminescent material 1120 during operation of the light source 114. As a result, at a given power spectral density of the primary light and the secondary light, a single temperature can be assigned to both the light-emitting diode 118 and the luminescent material 120 as comprised by the light source 114.

Illumination light 116 as generated by the light source 114 may propagate from the light source 114 to the object 112. In FIG. 1, the illumination light 116 generated by the light source 114 and propagating to the object 112 is illustrated by an arrow. The object 112 specifically may comprise at least one sample, which may fully or partially be analyzed by spectroscopic methods.

As apparent from FIG. 1, the spectrometer device 110 further comprises at least one broadband detector 128 configured for detecting detection light 130 from the object 112 in a spectral range at least partially comprising the spectral ranges of the primary light and the secondary light. While light propagating from the light source 114 to the object 112 may be referred to as illumination light 116, light propagating from the object 112 to the broadband detector 128 may be denoted as “detection light” 130. In FIG. 1, the detection light 130 is illustrated by an arrow. The detection light 130 may comprise at least one of illumination light 116 reflected by the object 112, illumination light 116 scattered by the object 112, illumination light 116 transmitted by the object 112, luminescence light generated by the object 112, e.g. phosphorescence or fluorescence light generated by the object 112 after optical, electrical or acoustic excitation of the object 112 by the illumination light 116 or the like. Thus, the detection light 130 may directly or indirectly be generated through the illumination of the object 112 by the illumination light 116.

The broadband detector 128 is configured for generating at least one primary detector signal upon detecting the detection light 130 in the spectral range of the primary light. The broadband detector 128 is further configured for generating at least one secondary detector signal upon detecting the detection light 130 in the spectral range of the secondary light. For example, the broadband detector 128 may comprise a plurality of detector elements 132, such as an array of photosensitive elements, for detecting detection light 130 in the spectral range of the primary light and the secondary light. The broadband detector 128 may comprise a pixelated broadband detector comprising a plurality of optically sensitive pixels or elements, as described in detail above. For example, the broadband detector 128 may comprise at least one first detector element 131 for detecting the detection light 130 in the spectral range of the primary light and at least one second detector element 133 for detecting the detection light 130 in the spectral range of the secondary light. Specifically, the first detector element 131 may be configured for generating the primary detector signal upon detecting the detection light 130 in the spectral range of the primary light. The second detector element 133 may be configured for generating the secondary detector signal upon detecting the detection light 130 in the spectral range of the secondary light. Each detector element 131, 133 may comprise a photosensitive material selected from at least one of PbS, PbSe, InSb, or HgCdTe. Alternatively, the broadband detector 128 may be a single detector 134 comprising a photosensitive material selected from at least one of PbS, PbSe, InSb, or HgCdTe. As a further alternative, the broadband detector 128 may be a single detector 134 having a photodiode, especially a photodiode comprising a material selected from at least one of Si, Ge, InGaAs, or ext. InGaAs. In FIG. 1, reference signs 132 and 134 are used together to indicate the arrangement of the plurality of detector elements 132 and the single detector 134 in the spectrometer device 110, although the spectrometer device 110 may comprise in one embodiment the plurality of detector elements 132 and, in an alternative embodiment, the single detector 134.

The broadband detector 128 may be adapted for generating electrical signals depending on the intensity of the incident light, wherein the electrical signals may, in particular, be provided to an evaluation unit 136 of the spectrometer device 110, as will be outlined in further detail below.

The spectrometer device 110 comprises at least one evaluation unit 136 for evaluating at least one of the primary detector signal and the secondary detector signal generated by the broadband detector 128 and for determining the spectroscopic information on the object 112 from at least one of the primary detector signal and the secondary detector signal. The broadband detector 128 may directly or indirectly provide the detector signals to the evaluation unit 136. Thus, the broadband detector 128 and the evaluation unit 136 may be directly or indirectly connected, as indicated by arrows in FIG. 1. The detector signals may be used as a “raw” detector signals and/or may be processed or preprocessed before further use, e.g. by filtering and the like. Thus, the broadband detector 128 may comprise at least one processing device and/or at least one preprocessing device, such as at least one of an amplifier, an analogue/digital converter, an electrical filter and a Fourier transformation.

As shown in FIG. 1, the spectrometer device 110 may further comprise at least one driving unit 138 for electrically driving the light source 114. The driving unit 138 may be configured for providing an electrical current to the LED 118, specifically for controlling an electrical current through the LED 118. Therein, as an example, the driving unit 138 may be configured for adapting and measuring a voltage provided to the LED 118, the voltage being required for achieving a specific electrical current through the LED 118. The driving unit 138, specifically, may comprise one or more of: a current source 140, a voltage source, a current measurement device, such as an Ampère-meter, a voltage measurement device 142, such as a Volt-meter, a power measurement device. Specifically, the driving unit 138 may comprise at least one current source 140 for providing at least one predetermined current to the LED 118, wherein the current source 140 specifically may be configured for adjusting or controlling a voltage applied to the LED 118 in order to generate the predetermined current. The driving unit 138, as an example, may comprise one or more electrical components, such as integrated circuits, for driving the light source 114. The driving unit 138 may be fully or partially integrated into the light source 114 or may be separated from the light source 114, the latter configuration being illustrated in FIG. 1.

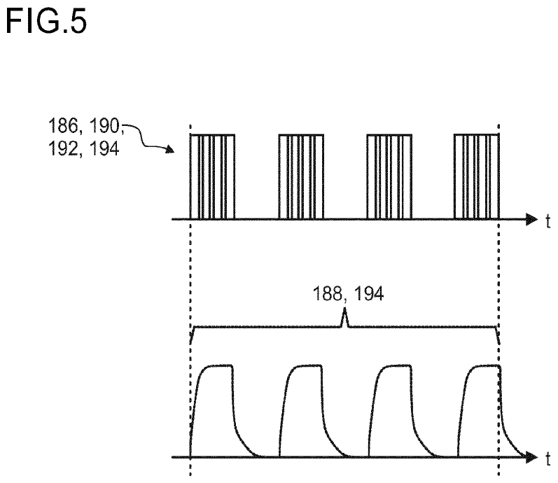

The driving unit 138 may specifically be comprised by the spectrometer device 110 in case the broadband detector 128 may be the single detector 134. However, the spectrometer device 110 may also comprise the driving unit 138 for other embodiments of the broadband detector 128. The driving unit 138 may be configured for driving the light-emitting diode 118 with at least one driving frequency. The driving frequency may specifically exceed an inverse of the decay constant t of the luminescent material 120. Further, the evaluation unit 136 may be configured for differentiating between the primary detector signal and the secondary detector signal by demodulation, such as by using a Fourier transform, in particular a fast Fourier transform. Thus, the spectrometer device 110 may be configured for pulse duration modulation of the light source 114 by using the driving unit 138. As can be seen in FIG. 5 below, the pulse duration modulation may be achieved by using a pulse train.

As outlined above, and as shown in FIG. 1, the spectrometer device 110 comprises the at least one evaluation unit 136 for evaluating at least one of the primary detector signal and the secondary detector signal generated by the broadband detector 128 and for deriving the spectroscopic information on the object 112 from at least one of the primary detector signal and the secondary detector signal. Specifically, the evaluation unit 136 may be configured for evaluating both the primary detector signal and the secondary detector signal as generated by the broadband detector 128. As a particular advantage of the thermal coupling 127 between the light-emitting diode 118 and the luminescent material 120 as indicated above, the single temperature of the light source 114 can be determined as temperature information 137 from the primary detector signal, wherein the temperature information 137 comprising the single temperature of the light source 114 which has previously been determined, is concurrently be determined, or will subsequently be determined in this fashion can be used for deriving the spectroscopic information on the object 112 from the secondary detector signal, whereby the temperature information 137 about the single temperature of the light source 114 is taken into account. Alternatively or in addition, the temperature information 137 about the single temperature of the light source 114 can, however, be determined from the secondary detector signal, while the spectroscopic information on the object can be derived from the primary detector signal by taking into account the temperature information 137 about the single temperature of the light source 114 as determined from the secondary detector signal. In this fashion, a heat-up of both the light-emitting diode 118 and the luminescent material 120 during the operation of the light source 114 can be determined and used for correcting the spectroscopic information on the object.

The evaluation unit 136 may be or may comprise one or more integrated circuits, such as one or more application-specific integrated circuits (ASICs), and/or one or more data processing devices 144, such as one or more of computers, digital signal processors (DSP), field programmable gate arrays (FPGA), preferably one or more microcomputers and/or microcontrollers. Additional components may be comprised, such as one or more preprocessing devices 146 and/or data acquisition devices, such as one or more devices for receiving and/or preprocessing of the detector signals, such as one or more AD-converters and/or one or more filters. Further, the evaluation unit 136 may comprise one or more data storage devices 148, as shown in FIG. 1. Further, the evaluation unit 136 may comprise one or more interfaces, such as one or more wireless interfaces and/or one or more wire-bound interfaces.

The spectrometer device 110 further may comprise one or more optical components 150, e.g. such as one or more of at least one mirror, at least one lens, at least one aperture and at least one wavelength-selective element 152. The wavelength-selective element 152 may be arranged such that the broadband detector 128 generates the at least one primary detector signal upon detecting the detection light 130 in the spectral range of the primary light and the at least one secondary detector signal upon detecting the detection light 130 in the spectral range of the secondary light. As shown in FIG. 1, the wavelength selection by the at least one wavelength-selective element 152 may take place in the at least one beam path of the illumination light 116, thereby selecting and/or modifying a wavelength of the illumination of the object 112, and/or in the detection beam path of the detection light 130, thereby selecting and/or modifying a wavelength of detection, e.g. for the broadband detector 128 in general and/or for each of the detector elements 131, 133. The wavelength-selective element 152 may comprise at least one of a wavelength-selective element 152 disposed in a beam path of the illumination light 116 or a wavelength-selective element 152 disposed in a beam path of the detection light 130. The wavelength-selective element 152 may specifically be selected from at least one of a tunable wavelength-selective element or a wavelength-selective element having a fixed transmission spectrum.

For example, the wavelength-selective element 152 may be arranged in the detection beam path of the detection light 130. The wavelength-selective element 152 may be configured for guiding the detection light 130 in the spectral range of the primary light on the first detector element 131 comprised by the broadband detector 128 such that the broadband detector 128 detects the detection light 130 in the spectral range of the primary light and, thus, generates the primary detector signal. The wavelength-selective element 152 may further be configured for guiding the detection light 130 in the spectral range of the secondary light on the second detector element 133 comprised by the broadband detector 128 such that the broadband detector 128 detects the detection light 130 in the spectral range of the secondary light and, thus, generates the secondary detector signal. Alternatively, the broadband detector 128 may be the single detector 134, as outlined above, and the wavelength-selective element 152 may be a tunable wavelength-selective element, such that the spectral range to be detected by the broadband detector 128 can be adjusted.

The spectrometer device 110 as represented in a schematic fashion in FIG. 1 is configured for obtaining spectroscopic information on the at least one object 112. In particular, the spectrometer device 110 may be configured for obtaining an item of information, e.g. on at least one object 112 and/or radiation emitted by the object 112, characterizing at least one optical property of the object 112, more specifically at least one item of information characterizing, e.g. qualifying and/or quantifying, at least one of a transmission, an absorption, a reflection and an emission of the object 112. As an example, the at least one item of spectral information may comprise at least one intensity information, e.g. information on an intensity of light being at least one of transmitted, absorbed, reflected or emitted by the object 112, e.g. as a function of a wavelength or wavelength sub-range over one or more wavelengths, e.g. over a range of wavelengths. Thus, the spectrometer device 110 may be configured for acquiring at least one spectrum or at least a part of a spectrum of detection light 130 propagating from the object 112 to the broadband detector 128. The spectrum may describe the radiometric unit of spectral flux, e.g. given in units of watt per nanometer (W/nm), or other units, e.g. as a function of the wavelength of the detection light 130. Thus, the spectrum may describe the optical power of light, e.g. in the NIR spectral range, in a specific wavelength band. The spectrum may contain one or more optical variables as a function of the wavelength, e.g. the power spectral density, electric signals derived by optical measurements and the like. The spectrum may specifically contain the spectral range of the primary light and of the secondary light. The spectrometer device 110 may specifically be a portable spectrometer device, e.g. being part a mobile device or may be attachable to a mobile device, such as a notebook computer, a tablet, a cell phone, such as a smart phone, a smartwatch and/or a wearable computer (not shown in FIG. 1).

In FIG. 2, a schematic cross-sectional view of a light source 114 is shown. The at least one light source 114 of the spectrometer device 110 may be configured for generating or providing to electromagnetic radiation in one or more of the infrared, the visible and the ultraviolet spectral range. Due to the fact that many material properties or properties on the chemical constitution of many objects 112 may be derived from the near-infrared spectral range, light used for the typical purposes of the present invention is light in the infrared (IR) spectral range, more preferred, in the near-infrared (NIR) and/or the mid infrared spectral range (MidIR), especially the light having a wavelength of 1 μm to 5 μm, preferably of 1 μm to 3 μm. The light source 114 comprises the at least one light-emitting diode 118 and the at least one luminescent material 120 for light-conversion of primary light generated by the light-emitting diode 118. The LED 118 and the luminescent material 120, together, may form the phosphor LED 122, as described above.

The phosphor LED 122 as illustrated in FIG. 2 may comprise one or more functional components. Specifically, the phosphor LED 122 may comprise one or more substrates 154, specifically one or more electrically insulating substrates 154. In particular, the phosphor LED 122 may comprise one or more ceramic substrates 156, as shown in FIG. 2. The substrate 154 may be configured for holding the at least one LED die 124 and the at least one luminescent material 120. Further, the at least one substrate 154 may hold or comprise one or more components of electrical connectivity, such as one or more contact pads 158 as shown in FIG. 2 and/or one or more electrical leads, such as one or more metallic contacts and/or one or more metallic leads. The substrate 154 may be configured to serve as a heat sink. Heat may be generated in the LED die 124, such as due to a limited conversion of electrical energy into photonic energy, as well as in the luminescent material 120, e.g. during the conversion process. Said heat may be dissipated in the substrate 154, such as in ceramic substrate.

As shown in FIG. 2, the phosphor LED 122 may comprise the light-emitting diode 118. The light-emitting diode 118 may be configured for converting electrical current into primary light, such as blue primary light, using at least one LED chip and/or the at least one LED die 124 as illustrated in FIG. 2. Specifically, p-n-diodes may be used. As an example, one or more LEDs 118 selected from the group of an LED 118 on the basis of indium gallium nitride (InGaN), an LED 118 on the basis of GaN, an LED 118 on the basis of InGaN/GaN alloys or combinations thereof and/or other LEDs 118 may be used. Additionally or alternatively, quantum well LEDs 118 may also be used, such as one or more quantum well LEDs 118 on the basis of InGaN. Additionally or alternatively, superluminescence LEDs (sLED) and/or Quantum cascade lasers may be used. As further apparent from FIG. 2, the phosphor LED may comprise the at least one luminescent material 120 configured for light-conversion of the primary light generated by the light-emitting diode 118. Various types of conversion and/or luminescence are known and may be used in the context of the present invention. Specifically, the luminescent material 120 may comprise at least one of: Cerium-doped YAG (YAG:Ce3+, or Y3Al5O12:Ce3+); rare-earth-doped Sialons; copper- and aluminum-doped zinc sulfide (ZnS:Cu,Al).

The luminescent material 120 specifically may form at least one layer. Generally, various alternatives of positioning the luminescent material 120 with respect to the light-emitting diode 118 are feasible, alone or in combination. Firstly, the luminescent material 120, e.g., at least one layer of the luminescent material 120, such as the phosphor, may be positioned directly on the light-emitting diode 118, e.g. with no material in between the LED 118 and the luminescent material 120 or with one or more transparent materials in between, such as with one or more transparent materials, specifically transparent for the primary light, in between the LED and the luminescent material 120. Thus, as an example, a coating of the luminescent material 120 may be placed directly or indirectly on the LED 118 (not shown). Additionally or alternatively, the luminescent material 120, as an example, may form at least one converter body 160, such as at least one converter disk, which may also be referred to as converter platelet. The converter body 160 may be placed on top of the LED 118, e.g. by adhesive attachment of the converter body 160 to the LED 118, as illustrated in FIG. 2. Additionally or alternatively, the luminescent material 120 may also be placed in a remote fashion, such that the primary light from the LED 118 has to pass an intermediate optical path before reaching the luminescent material 120 (not shown). Again, as an example, the luminescent material 120 in the remote placement may form a solid body or converter body 160, such as a disk or converter disk. In the intermediate optical path, one or more optical elements may be placed, such as one or more of a lens, a prism, a grating, a mirror, an aperture or a combination thereof. Thus, specifically, an optical system having imaging properties may be placed in between the LED 118 and the luminescent material 120, in the intermediate optical path. Thereby, as an example, the primary light may be focused, or bundled onto the converter body 160.

In the light source 114, specifically the phosphor LED 122, the at least one luminescent material 120 may be located with respect to the light-emitting diode 118 such that a heat transfer from the light-emitting diode 118 to the luminescent material 120 is possible. More specifically, the luminescent material 120 may be located such that a heat transfer by one or both of thermal radiation and heat conduction is possible, more preferably by heat conduction. Thus, as an example, the luminescent material 120 may be in thermal contact and/or in physical contact with the light-emitting diode 118 as illustrated in FIG. 2. Thereby, generally, a temperature of the luminescent material 120 and a temperature of the light-emitting diode 118 may be coupled.

As illustrated in FIG. 2, the light source 114, specifically the phosphor LED 122, may comprise further components such as at least one side coat 162 covering at least one side, such as a top side, a bottom side and/or one or more lateral sides of at least of: the substrate 154, the contact pad 158, the light-emitting diode 118 and the luminescent material 120. Specifically, the side coat 162 may cover gaps and/or interspaces that may be present in the layered set-up of the light source 114 as shown in FIG. 2. Further components of the light source 114, specifically components, which are not shown in FIG. 2, are feasible. Generally, the light source 114, in particular the phosphor LED 122, may be packaged in one housing (not shown in FIG. 2) or may be unpackaged. Thus, the LED 118 and the at least one luminescent material 120 for light-conversion of the primary light generated by the light-emitting diode 118 may specifically be housed in a common housing. Alternatively, however, the LED 118 may also be an unhoused or bare LED 118, as illustrated in FIG. 2.

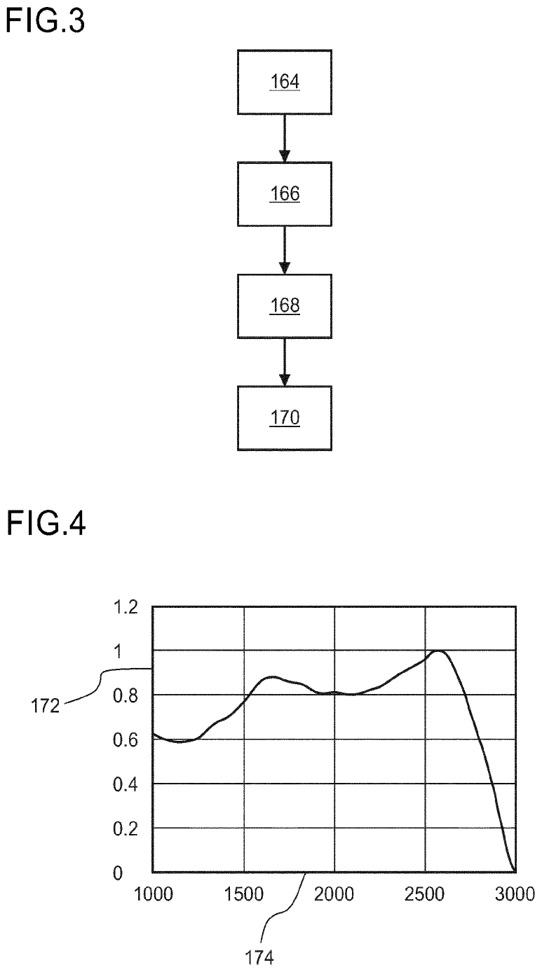

FIG. 3 shows a flow chart of an exemplary embodiment of a method of obtaining spectroscopic information on at least one object 112. The method comprises the following steps that may be performed in the given order. However, a different order may also be possible. In particular, one, more than one or even all of the meth-od steps may be performed once or repeatedly. Further, the method steps may be performed successively or, alternatively, one or more of the method steps may be performed in a timely overlapping fashion or even in a parallel fashion and/or in a combined fashion. The method may further comprise additional method steps that are not listed.

The method comprises:
a) (denoted by reference number 164) providing at least one spectrometer device 110 according to the present invention, such as according to the exemplary embodiment of FIG. 1 and/or according to any other embodiment disclosed herein;
b) (denoted by reference number 166) illuminating the object 112 with illumination light 116 generated by the light source 114, the light source 114 comprising at least one light-emitting diode 118 and at least one luminescent material 120 for light-conversion of primary light generated by the light-emitting diode 118 into secondary light, wherein the illumination light 116 at least partially comprises the primary light and the secondary light;
c) (denoted by reference number 168) detecting detection light 130 from the object 112 in a spectral range at least partially comprising the spectral ranges of the primary light and the secondary light, by using at least one broadband detector 128, wherein the broadband detector 128 is configured for generating at least one primary detector signal upon detecting the detection light 130 in the spectral range of the primary light, wherein the broadband detector 128 is configured for generating at least one secondary detector signal upon detecting the detection light 130 in the spectral range of the secondary light; and
d) (denoted by reference number 170) evaluating the primary detector signal and the secondary detector signal generated by the broadband detector 128 by using the evaluation unit 136, determining temperature information on the light source 114 from one of the primary detector signal or the secondary detector signal, and deriving the spectroscopic information on the object 112 from the other of the primary detector signal or the secondary detector signal by taking into account the temperature information on the light source 114.

Step d) may comprise evaluating the primary detector signal generated by the broadband detector 128 determining the temperature information 137 on the light source 114 from the primary detector signal and the spectroscopic information on the object 112 from the secondary detector signal by taking into account the temperature information 137 on the light source 114 as determined from the primary detector signal. Alternatively or in addition, step d) may comprise determining the temperature information 137 on the light source 114 from the secondary detector signal and the spectroscopic information on the object 112 from the primary detector signal by taking into account the temperature information 137 on the light source 114 as determined from the secondary detector signal.

The spectrometer device 110 may further comprise, as outlined above, the at least one driving unit 138 for electrically driving the light source 114. The method may comprise, specifically in step b), driving the light-emitting diode 118 with at least one driving frequency by using the driving unit 138. The driving frequency may be higher than an inverse of a time constant t of the luminescent material 120. Specifically, this operation mode of the light source 114 may also be referred to as pulse duration modulation. The evaluating in step d) may comprise differentiating between the primary detector signal and the secondary detector signal by demodulation, such as by using a Fourier transform, in particular a fast Fourier transform. As can be seen in FIG. 5 below, the light-emitting diode 118 can be modulated by using a pulse train, specifically by using the driving unit 138.

In FIG. 4, a diagram of a spectral response of an exemplary broadband detector 128 is shown. Specifically, the diagram of FIG. 4 shows a spectral response comprising a normalized signal intensity in arbitrary units 172 as a function of wavelength 174. As can be seen in FIG. 4, the broadband detector 128 may be configured for detecting detection light 130 from the object 112 in a spectral range of 1000 nm to 3000 nm.

FIG. 5 shows a diagram of a pulse duration modulation. Specifically, in the diagram of FIG. 5, driving pulses applied to the light-emitting diode 118 are shown in the time domain (denoted by reference number 186) together with the resulting pulses of secondary light in the time domain (denoted by reference number 188). As can be seen in FIG. 6, a pulse train 190 may be applied to the light-emitting diode 118, specifically by using the driving unit 138, comprising a driving frequency which exceeds an inverse of the time constant T of the luminescent material 120. Since the pump LED 118 may be faster than the luminescent material 120, the pulses of the secondary light may not follow the fast driving of the LED 118 and, thus, the pulse form applied to the pump LED 118 may be used such that a frequency domain information obtained from a fast Fourier transform may provide both spectroscopic information from the primary detector signal and the second detector signal with the single detector 134.

As schematically depicted in FIG. 5, the pulse train 190 comprises a consecutive sequence of pulses, wherein the sequence has a high frequency for individual pulses 192 but a lower frequency for pulse packages 194, especially in order to generate an excitation of at least one material being impinged by the pulse train 190. In particular, the high frequency sequence of the individual pulses 192 can be modulated by the lower frequency of the pulse packages 194, which can be expressed by a modulation frequency f₁. As indicated above, by using converter time constants τ_{g} and τ_{d}, wherein τ_{g} denotes a growth time constant and τ_{d} denotes a decay time constant, the modulation frequency f₁ can, especially, be expressed by equation (3) as

$${f}_{1} ≫ \frac{1}{max ( {τ}_{g} , {τ}_{d} )} \qquad ( 3 )$$

As a particular advantage thereof, the pulse train 190 allows, concurrently providing primary light having the high frequency of the individual pulses 192 as generated by the light-emitting diode 118 and secondary light having the lower modulation frequency f₁ of the pulse packages 194, wherein the lower modulation frequency f₁ of the pulse packages is selected in order to allow the luminescent material 120 to follow the excitation by the pulse packages 194 as provided by the pulse train. Herein, frequency multiplexing allows differentiating between the primary detector signal and the secondary detector signal both generated by the single detector 134. In this manner, both the temperature information 137 on the light source 114 can be determined and the spectroscopic information on the object 112 can be derived by taking into account the temperature information on the light source 114 from the detector signal generated by the single detector 134.

### LIST OF REFERENCE NUMBERS

110 spectrometer device
112 object
114 light source
116 illumination light
118 light-emitting diode
120 luminescent material
121 semiconductor material
122 phosphor light-emitting diode
124 LED die
126 housing
127 thermal coupling
128 broadband detector
130 detection light
131 first detector element
132 plurality of detector elements
133 second detector element
134 single detector
136 evaluation unit
137 temperature information
138 driving unit
140 current source
142 voltage measurement device
144 data processing devices
146 preprocessing devices
148 data storage devices
150 optical component
152 wavelength-selective element
154 substrate
156 ceramic substrate
158 contact pad
160 converter body
162 side coat
164 providing the spectrometer device
166 illuminating the object
168 detecting detection light
170 evaluating at least one of the primary detector signal and the secondary detector signal
172 normalized signal intensity
174 wavelength
186 driving pulses
188 pulses of secondary light
190 pulse train
192 individual pulse
194 pulse package

1. A spectrometer device for obtaining spectroscopic information on at least one object, the spectrometer device comprising:
i. at least one light source for generating illumination light for illuminating the object, the light source comprising at least one light-emitting diode and at least one luminescent material for light-conversion of primary light generated by the light-emitting diode into secondary light, wherein the illumination light at least partially comprises the primary light and the secondary light;
ii. at least one broadband detector for detecting detection light from the object in a spectral range at least partially comprising the spectral ranges of the primary light and the secondary light, wherein the broadband detector is configured for generating at least one primary detector signal upon detecting the detection light in the spectral range of the primary light, wherein the broadband detector is further configured for generating at least one secondary detector signal upon detecting the detection light in the spectral range of the secondary light; and
iii. at least one evaluation unit for evaluating the primary detector signal and the secondary detector signal generated by the broadband detector, for determining temperature information on the light source from one of the primary detector signal or the secondary detector signal, and for deriving the spectroscopic information on the object from the other of the primary detector signal or the secondary detector signal by taking into account the temperature information on the light source.

2. The spectrometer device according to claim 1, wherein the evaluation unit is configured for determining
the temperature information on the light source from the primary detector signal and the spectroscopic information on the object from the secondary detector signal by taking into account the temperature information on the light source as determined from the primary detector signal; or
the temperature information on the light source from the secondary detector signal and the spectroscopic information on the object from the primary detector signal by taking into account the temperature information on the light source as determined from the secondary detector signal.

3. The spectrometer device according to claim 1, wherein the light-emitting diode and the luminescent material are thermally coupled.

4. The spectrometer device according to claim 1, wherein the broadband detector is configured for detecting detection light from the object in a spectral range of 200 nm to 5 pm.

5. The spectrometer device according to claim 1, wherein the broadband detector
comprises a plurality of detector elements for detecting detection light in the spectral ranges of the primary light and the secondary light, each of the detector elements comprising a photosensitive material or a photodiode; or
is a single detector comprising the photosensitive material or the photodiode.

6. The spectrometer device according to claim 5, wherein the evaluation unit is configured for differentiating between the primary detector signal and the secondary detector signal by frequency multiplexing of a combined detector signal generated by the single detector, wherein the combined detector signal comprises both the primary detector signal and the secondary detector signal.

7. The spectrometer device according to claim 1, further comprising at least one driving unit for electrically driving the light source, wherein the driving unit is configured for driving the light-emitting diode with at least one driving frequency, wherein the driving frequency exceeds an inverse of a time constant T of the luminescent material.

8. The spectrometer device according to claim 1, wherein the primary light is at least partially located in a spectral range of 380 nm to 1000 nm, and wherein the secondary light is at least partially located in a spectral range of 1 pm to 5 pm.

9. The spectrometer device according to claim 1, wherein the light source comprises a phosphor light-emitting diode.

10. The spectrometer device according to claim 1, wherein the spectrometer device further comprises at least one wavelength-selective element, wherein the wavelength-selective element is arranged such that the broadband detector generates the at least one primary detector signal upon detecting the detection light in the spectral range of the primary light and the at least one secondary detector signal upon detecting the detection light in the spectral range of the secondary light.

11. A method of obtaining spectroscopic information on at least one object, the method comprising:
a) providing at least one spectrometer device according to claim 1;
b) illuminating the object with illumination light generated by the light source, the light source comprising at least one light-emitting diode and at least one luminescent material for light-conversion of primary light generated by the light-emitting diode into secondary light, wherein the illumination light at least partially comprises the primary light and the secondary light;
c) detecting detection light from the object in a spectral range at least partially comprising the spectral ranges of the primary light and the secondary light, by using at least one broadband detector, wherein the broadband detector is configured for generating at least one primary detector signal upon detecting the detection light in the spectral range of the primary light, wherein the broadband detector is configured for generating at least one secondary detector signal upon detecting the detection light in the spectral range of the secondary light; and
d) evaluating the primary detector signal and the secondary detector signal generated by the broadband detector by using the evaluation unit, determining temperature information on the light source from one of the primary detector signal or the secondary detector signal, and deriving the spectroscopic information on the object from the other of the primary detector signal or the secondary detector signal by taking into account the temperature information on the light source.

12. The method according to claim 11, wherein step d) comprises determining
the temperature information on the light source from the primary detector signal and the spectroscopic information on the object from the secondary detector signal by taking into account the temperature information on the light source as determined from the primary detector signal;
the temperature information on the light source from the secondary detector signal and the spectroscopic information on the object from the primary detector signal by taking into account the temperature information on the light source as determined from the secondary detector signal.

13. The method according to claim 11, wherein the light-emitting diode and the luminescent material are thermally coupled.

14. The method according to claim 11, the spectrometer device further comprising at least one driving unit for electrically driving the light source, wherein the method comprises driving the light-emitting diode with at least one driving frequency by using the driving unit, wherein the driving frequency is higher than an inverse of a time constant T of the luminescent material.

15. A computer program comprising instructions, wherein when the program is executed by the spectrometer device according to claim 1, the instructions cause the spectrometer device to perform a method comprising:
a) illuminating the object with illumination light generated by the light source, the light source comprising at least one light-emitting diode and at least one luminescent material for light-conversion of primary light generated by the light-emitting diode into secondary light, wherein the illumination light at least partially comprises the primary light and the secondary light;
b) detecting detection light from the object in a spectral range at least partially comprising the spectral ranges of the primary light and the secondary light, by using at least one broadband detector, wherein the broadband detector is configured for generating at least one primary detector signal upon detecting the detection light in the spectral range of the primary light, wherein the broadband detector is configured for generating at least one secondary detector signal upon detecting the detection light in the spectral range of the secondary light; and
c) evaluating the primary detector signal and the secondary detector signal generated by the broadband detector by using the evaluation unit, determining temperature information on the light source from one of the primary detector signal or the secondary detector signal, and deriving the spectroscopic information on the object from the other of the primary detector signal or the secondary detector signal by taking into account the temperature information on the light source.

16. The spectrometer device according to claim 1, wherein the broadband detector is configured for detecting detection light from the object in a spectral range of 300 nm to 3 pm.

17. The spectrometer device according to claim 1, wherein the broadband detector is configured for detecting detection light from the object in a spectral range of 400 nm to 2.5 pm.

18. A computer program comprising instructions, wherein when the program is executed by a spectrometer device, the instructions cause the spectrometer device to perform at least steps b) to d) of the method according to claim 11.
